(19) United States
(12) Patent Application Publication
(10) Pub. No.: US 2025/0062779 A1
(43) Pub. Date: Feb. 20, 2025

(54) METHODS AND APPARATUS FOR INFORMATION AND DATA TRANSMISSION

(71) Applicant: ZTE Corporation, Shenzhen (CN)

(72) Inventors: Chulong LIANG, Shenzhen (CN); Wei ZHAO, Shenzhen (CN); Jin XU, Shenzhen (CN); Liguang LI, Shenzhen (CN); Guanghui YU, Shenzhen (CN); Jian KANG, Shenzhen (CN); Qiang FU, Shenzhen (CN)

(21) Appl. No.: 18/933,200

(22) Filed: Oct. 31, 2024

Related U.S. Application Data
(63) Continuation of application No. PCT/CN2022/129016, filed on Nov. 1, 2022.

(51) Int. Cl. H03M 13/13; H03M 13/00; H04L 1/00

(52) U.S. Cl. CPC H03M 13/13; H03M 13/617; H04L 1/0064; H04L 1/0067

(57) ABSTRACT

Methods, apparatus, and systems that relate to rate matching scheme design for polar coding, PAC coding, or other pre-transformed polar coding are disclosed. In one example aspect, a method for digital communication includes determining, by a first node, an output bit sequence having E bits based on an input bit sequence having K bits, wherein the output bit sequence is determined by performing a polar transform with H components and a pre-transform; wherein the polar transform is based on H polar matrices G^{(N}^{₀}⁾, G^{(N}^{₁}⁾, . . . , G^{(N}^{_{H−0}}⁾, wherein E, K, H are integers greater than 1, wherein a polar matrix G^{(N}^{₀}⁾ is of size Nᵢ. The method also includes transmitting, by the first node, a signal including the output bit sequence to a second node.

### CROSS REFERENCE TO RELATED APPLICATIONS

This patent document is a continuation of and claims benefit of priority to International Patent Application No. PCT/CN2022/129016, filed on Nov. 1, 2022. The entire content of the before-mentioned patent application is incorporated by reference as part of the disclosure of this application.

### TECHNICAL FIELD

This patent document is directed generally to channel coding technique in communication systems.

### BACKGROUND

Mobile telecommunication technologies are moving the world toward an increasingly connected and networked society. In comparison with the existing wireless networks, next generation systems and communication techniques will need to support a much wider range of use-case characteristics and provide a more complex and sophisticated range of access requirements and flexibilities.

Long-Term Evolution (LTE) is a standard for wireless communication for mobile devices and data terminals developed by 3rd Generation Partnership Project (3GPP). LTE Advanced (LTE-A) is a wireless communication standard that enhances the LTE standard. The 5th generation of wireless system, known as 5G, advances the LTE and LTE-A wireless standards and is committed to supporting higher data-rates, large number of connections, ultra-low latency, high reliability and other emerging business needs.

### SUMMARY

This patent document discloses techniques, among other things, rate matching design for polar coding, PAC coding and/or other pre-transformed polar coding schemes.

In one example aspect, a first digital communication method is disclosed. The method includes determining, by a first node, an output bit sequence having E bits based on an input bit sequence having K bits, wherein the output bit sequence is determined by performing a polar transform with H components and a pre-transform; wherein the polar transform is based on H polar matrices G^{(N}^{₀}⁾, G^{(N}^{₁}⁾, . . . , G^{(N}^{_{H−0}}⁾, wherein E, K, H are integers greater than 1, wherein a polar matrix G^{(N}^{ᵢ}⁾ is of size Nᵢ; and transmitting, by the first node, a signal including the output bit sequence to a second node.

In another example aspect, another method of wireless communication is disclosed. The method includes receiving, by a second node, a signal including an output bit sequence having E bits from a first node; and determining, by the second node, an input bit sequence having K bits based on the signal, wherein the output bit sequence is determined by performing a polar transform with H components and a pre-transform; wherein the polar transform is based on H polar matrices G^{(N}^{₀}⁾, G^{(N}^{₁}⁾, . . . , G^{(N}^{_{H−0}}⁾, wherein E, K, H are integers greater than 1, wherein a polar matrix G^{(N}^{ᵢ}⁾ is of size Nᵢ.

In yet another example aspect, a wireless communication device comprising a process that is configured or operable to perform the above-described methods is disclosed.

In yet another example aspect, a computer readable storage medium is disclosed. The computer-readable storage medium stores code that, upon execution by a processor, causes the processor to implement an above-described method.

### BRIEF DESCRIPTION OF THE DRAWING

FIG. 1 provides an exemplary diagram of factor graph of the polar matrix G⁽³²⁾.

FIG. 2A provides exemplary diagram of polar encoding with rate matching in 3GPP 5G standard.

FIG. 2B provides exemplary diagram of PAC encoding.

FIG. 3 shows an exemplary block diagram of a convolution transform with either a convolution vector g=[g₀, g₁, . . . , gₘ] or a convolution polynomial g(D)=g₀+g₁·D+ . . . +gₘ₋₁·D^{m-1}+gₘ·D^{m} over GF(2).

FIGS. 4A-4C show examples of rate matching pre-transformed polar coding.

FIG. 5 shows an exemplary block diagram of a pre-transform defined by a recursive feedback polynomial.

FIG. 6 shows an exemplary block diagram of a pre-transform defined by both a generator polynomial and a recursive feedback polynomial.

FIG. 7 shows an exemplary block diagram of a hardware platform that may be a part of a network device or a communication device.

FIG. 8 shows an example of network communication including a base station (BS) and user equipment (UE) based on some implementations of the disclosed technology.

FIG. 9 is a flowchart representation of a method for digital communication in accordance with one or more embodiments of the present technology.

FIG. 10 is a flowchart representation of another method for digital communication in accordance with one or more embodiments of the present technology.

### DETAILED DESCRIPTION

Headings for the various sections below are used to facilitate the understanding of the disclosed subject matter and do not limit the scope of the claimed subject matter in any way. Accordingly, one or more features of one section can be combined with one or more features of another section. Furthermore, 5G terminology is used for the sake of clarity of explanation, but the techniques disclosed in the present document are not limited to 5G technology only and may be used in wireless systems that implemented other protocols.

This application proposes methods and apparatuses related to rate matching schemes for pre-transformed polar coding in wireless communication systems.

In the fifth generation (5G) mobile communications standard of the 3^{rd} Generation Partnership Project (3GPP), low-density parity-check (LDPC) codes are used for data transmission. However, LDPC codes is worse than polar codes in short payload size (also called transport block size (TBS)). Also, LDPC codes have high error floors (at block error rate (BLER) of 0.0001). To fulfill the future ultra-reliable low latency communication (URLLC), we have to design more powerful channel codes.

Polarization-adjusted convolutional (PAC) codes can achieve finite-length bounds in moderate decoding complexity. PAC codes are a revolution of polar codes. As a result, PAC codes have code lengths with power of 2 (N=2ⁿ with positive integer n) as polar codes. However, to efficiently transmitting a payload (or transport block (TB)) in different wireless channel environments, it does not always have a code length of N=2ⁿ in time and frequency resources allocated by a base station (BS). As a result, rate matching schemes are needed for applying PAC codes in wireless communications. In this application, methods and apparatus for design in rate matching for polar coding, PAC coding, or other pre-transformed polar coding are proposed with good performance.

### Introduction

### Notations

GF(2) denotes the Galois field of size 2 with two elements “0” and “1”.

br(i) is the bit-reversal function.

floor(x) denotes the largest integer not greater than x.

ceil(x) denotes the smallest integer not less than x.

round(x) is the round function such that round(x) is the integer closest to x, for example, round (3.2)=3, round (4.8)=5, round (2.5)=3, round (−1.9)=−2, round (−3.4)=−3.

max(x,y) denotes the maximum value between x and y, i.e.,

$$max ( x , y ) = \{ \begin{matrix}x , & x \geq y , \\ y , & y > x .\end{matrix}$$

mod(x, y) denotes the remainder of x divided by y. For example, mod(5, 3)=2 and mod(3, 5)=3.

X_{i, j} denotes the element in the i-th row and j-th column of a matrix X, where a boldface capital letter is used to represent a matrix.

[x₀, x₁, . . . , x_{Y-1}] denotes a sequence (or a vector) of length Y containing elements x₀, x₁, . . . , x_{Y-1}. A boldface small letter x is used to represent a sequence (or a vector) [x₀, x₁, . . . , x_{Y-1}].

{x₀, x₁, . . . , x_{Y-1}} denotes a set with Y distinct elements x₀, x₁, . . . , x_{Y-1}, i.e., for any i≠j, xᵢ≠xⱼ.

<x₀, x₁, . . . , x_{Y-1}>denotes an ordered set with Y distinct elements x₀, x₁, . . . , x_{Y-1}, i.e., for any i≠j, xᵢ≠xⱼ. Let X=<x₀, x₁, . . . , x_{Y-1}>, X (i) denotes the i-th element x; in the ordered set X.

For a set X, |X| denotes the set size, i.e., the number of elements in the set X.

Z_{N}={0, 1, . . . , N−2, N−1} denotes the integer set containing all non-negative integers smaller than N.

Indices for sequences, vectors, or matrices are starting from zero.

### Introduction to Polar Matrix

This section introduces some concepts of use of a polar matrix according to various embodiments.

We denote G^{(N)} as a polar transform matrix (or simply, polar matrix) with N rows and N columns, where N is power of 2, i.e., N=2ⁿ and n is a positive integer. n is called the order of the polar matrix of G^{(N)} and N is called the polar matrix size of G^{(N)}, i.e., G^{(N)} is of size N.

G^{(N)} can be one of the following:

$$1 ) {G}^{( N )} = {( {P}^{( 2 )} )}^{⊗ n} ; \\ 2 ) {G}^{( N )} = {B}^{( N )} \cdot {( {P}^{( 2 )} )}^{⊗ n} ; \\ 3 ) {G}^{( N )} = {P}^{( N )} ; \\ 4 ) {G}^{( N )} = {B}^{( n )} \cdot {P}^{( N )} ;$$

Here, all the matrix operations are over GF(2), e.g.,

$${P}^{( N )} = [ \begin{matrix}{P}^{( N / 2 )} & 0 \\ {P}^{( N / 2 )} & {P}^{( N / 2 )}\end{matrix} ] , \\ {P}^{( 2 )} = [ \begin{matrix}1 & 0 \\ 1 & 1\end{matrix} ] , \\ {P}^{( 1 )} = [ 1 ] , {( {P}^{( 2 )} )}^{⊗ n}$$

is the n-th Kronecker power of the matrix P⁽²⁾, and B^{(N)} is a bit-reversal permutation matrix with N rows and N columns, 0 is an all-zero matrix with N/2 rows and N/2 columns.

Let B_{i,j} ^{(N)} be the element at the i-th row and j-th column of the bit-reversal permutation matrix B^{(N)}. Then,

$${B}_{i , j}^{( N )} = \{ \begin{matrix}1 , & j = br ( i ) , \\ 0 & j \neq br ( i ) ,\end{matrix}$$

for 0≤i<N and 0≤j<N, where br(i) is the bit-reversal function defined as

$$br ( i ) = {\sum }_{k = 0}^{n - 1} {b}_{k} \cdot {2}^{n - 1 - k}$$

and [bₙ₋₁, bₙ₋₂, . . . , b₁, b₀] is the n-bit binary expansion of the integer i, i.e.,

$$i = {\sum }_{k = 0}^{n - 1} {b}_{k} \cdot {2}^{k} .$$

A sequence (or a vector) x of length N over GF(2) multiplying the polar matrix G^{(N)} over GF(2) is called polar transform on the sequence (vector) x. Denote y=x·G^{(N)}, where the vector-matrix multiplication is over GF(2). Then, y is the polar transform of x.

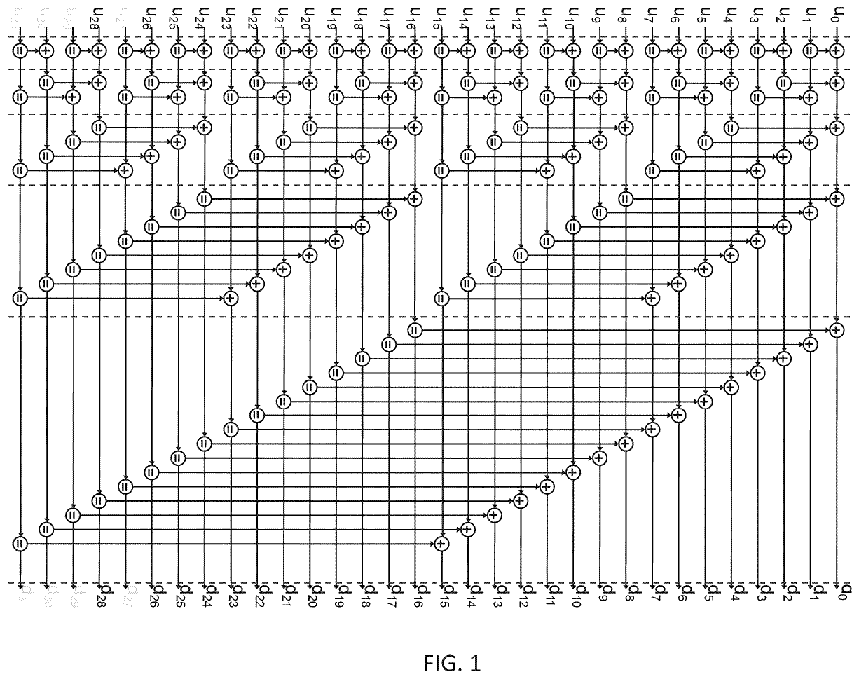

FIG. 1 shows the factor graph of the polar matrix G⁽³²⁾ of size N=32 and the matrix G⁽³²⁾ is shown below as:

### Introduction to 3GPP 5G Polar Coding

Some example embodiments of use of polar coding according to 3GPP 5G standard are disclosed in this section.

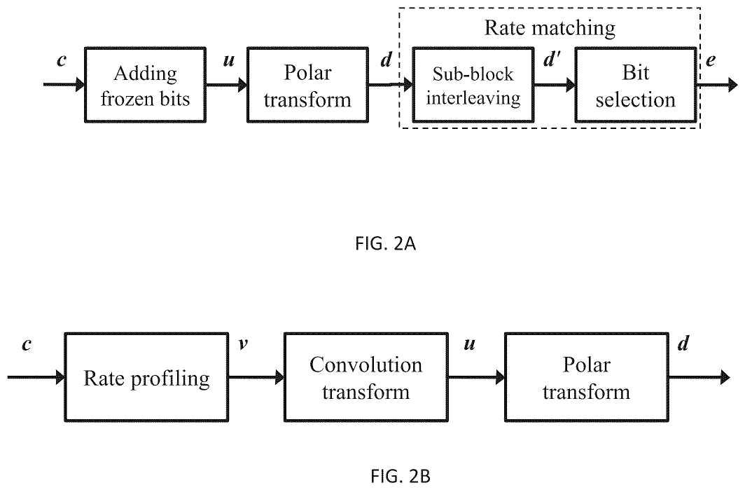

In the 3GPP 5G standard, polar codes are used in control channel transmission. The diagram of 5G polar coding with rate matching is shown in FIG. 2A.

Denote Q a data bit index set of size K, i.e., |Q|=K, where Q is a subset of an integer set Z_{N}={0, 1, . . . , N−2, N−1} containing all non-negative integers smaller than N. Then, the encoding of an input bit sequence c=[c₀, c₁, . . . , c_{K-2}, c_{K-1}] into an output bit sequence e=[e₀, e₁, . . . , e_{E-2}, e_{E-1}] for the 5G polar coding with a polar matrix G^{(N)} includes the following operations, where K is the length of the input bit sequence, E is the length of the output bit sequence, K and E are positive integers, K<N, and K<E.

As shown in FIG. 2A, there are 3 main steps involved in the process: adding frozen bits, polar transform and rate matching. The rate matching step further includes sub-block interleaving and bit selection.

(1) Adding frozen bits: The adding-frozen-bits operation combines N−K zero bits with the input bit sequence c to form a polar transform input sequence u=[u₀, u₁, . . . , u_{N-2}, u_{N-1}] of length N according to the data bit index set Q.

The polar transform input sequence u is determined by the input bit sequence c, the data bit index set Q, and the polar matrix size N as follows:

```
k = 0;
For i = 0 to N-1
    If i ϵ Q
      uᵢ = cₖ;
      k = k + 1;
    Else
      uᵢ = 0;
    End if
End for
```

(2) Polar transform: The polar transform is converting a first length-N bit sequence into a second length-N bit sequence by multiplying the first length-N bit sequence and the polar matrix G^{(N)} over GF(2). A polar transform output bit sequence d=[d₀, d₁, . . . , d_{N-2}, d_{N-1}] of length N is determined by the polar transform input sequence u and the polar matrix G^{(N)} as d=u·G^{(N)}, where the vector-matrix multiplication is over GF(2).

(3) Rate matching: The rate matching of polar coding in 5G includes two operations: Sub-block interleaving and bit selection.

(3.1) Sub-block interleaving: An interleaving output bit sequence d′=[d′₀, d′₁, . . . , d′_{N-2}, d′_{N-1}] of length N is determined by a sub-block interleaver pattern π of length 32, the polar transform output bit sequence d, and the polar matrix size N as follows.

```
For i = 0 to N-1
    j = floor(32i/N);
    Jᵢ = πⱼX(N/32) + mod(i, N/32);
    d′ᵢ = dⱼ_{ᵢ};
End for
```

where π=[π₀, π₁, π₂, π₃, π₄, π₅, π₆, π₇, π₈, π₉, π₁₀, π₁₁, π₁₂, π₁₃, π₁₄, π₁₅, π₁₆, π₁₇, π₁₈, π₁₉, π₂₀, π₂₁, π₂₂, π₂₃, π₂₄, π₂₅, π₂₆, π₂₇, π₂₈, π₂₉, π₃₀, π₃₁, ]=[0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31], and J=[J₀, J₁, . . . , J_{N-2}, J_{N-1}] is an interleaver pattern of length N determined by the sub-block interleaver pattern π and the polar matrix size N. The interleaver pattern J is a permutation of the integer sequence [0, 1, 2, . . . , N−2, N−1].

(3.2) Bit selection: There are three types of bit selection named as repetition, puncturing and shortening. With the interleaving output bit sequence d′, the length of the input bit sequence K, the length of the output bit sequence E, and the polar matrix size N, the output bit sequence e is determined as follows:
Repetition: For E≥N, eₖ=d′_{mod(k,N)}, k=0, 1, 2, . . . , E−2, E−1.
Puncturing: For E<N and K/E≤7/16, eₖ=d′_{N-E+k}, k=0, 1, 2, . . . , E−2, E−1.
Shortening: For E<N and K/E>7/16, eₖ=d′ₖ, k=0, 1, 2, . . . , E−2, E−1.

### Polarization-Adjusted Convolutional (PAC) Coding

Some example embodiments of PAC coding are disclosed in this section.

PAC codes is a class of pre-transformed polar codes. Specifically, PAC codes are polar codes using convolution transform.

The diagram of PAC coding is shown in FIG. 2B. Denote Q a data bit index set of size K, i.e., |Q|=K, where Q is a subset of an integer set Z_{N}={0, 1, . . . , N−2, N−1} containing all non-negative integers smaller than N. Then, the encoding of an input bit sequence c=[c₀, c₁, . . . , c_{K-2}, c_{K-1}] into an output bit sequence e=[e₀, e₁, . . . , e_{E-2}, e_{E-1}] by the polar matrix G^{(N)} includes the following operations, where K is the length of the input bit sequence, E is the length of the output bit sequence, K<N, K<E and K and E are positive integers.

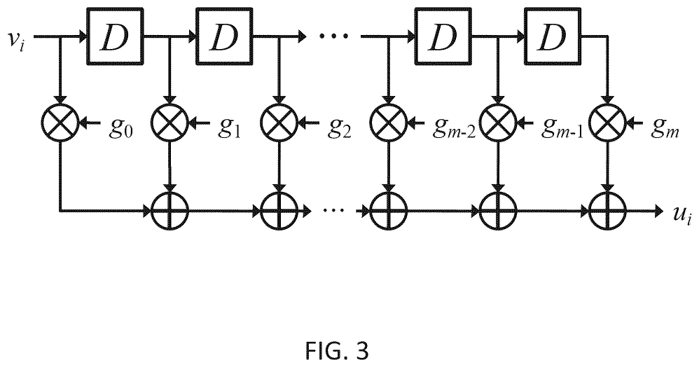

FIG. 3 discloses an example diagram for a convolution transform with either a convolution vector g=[g₀, g₁, . . . , gₘ] or a convolution polynomial g(D)=g₀+g₁·D+ . . . +gₘ₋₁·D^{m-1}+gₘ·D^{m} over GF(2).

(1) Rate profiling: The rate profiling is an operation same as the adding-frozen-bits operation in the 5G polar coding. Thus, two terms “adding-frozen-bits” and “rate profiling” are used interchangeably to refer to the same operation in this document. The rate-profiling operation combines N−K zero bits with the input bit sequence c to form a rate-profiling output sequence v=[v₀, v₁, . . . , v_{N-2}, v_{N-1}] of length N according to the data bit index set Q. Specifically, the rate-profiling output bit sequence v is determined by the input bit sequence c, the data bit index set Q, and the polar matrix size N as follows.

```
k = 0;
For i = 0 to N-1
    If i ϵ Q
      vᵢ = cₖ;
      k = k + 1;
    Else
      vᵢ = 0;
      End if
End for
```

(2) Convolution transform: the convolution transform is an operation converting a convolution input bit sequence of length N into a convolution output bit sequence of length N by performing convolution on the convolution input bit sequence and a generator bit sequence g=[g₀, g₁, . . . , gₘ₋₁, gₘ] of length-(m+1) defining a generator polynomial g(D)=g₀+g₁·D+ . . . +gₘ₋₁·D^{m-1}+gₘ·D^{m} over GF(2), where m is the memory length of the convolution transform or equivalently the generator polynomial degree of the generator polynomial g(D) and D is a dummy variable representing delay in a digital circuit.

The convolution transform with a generator polynomial g(D) is shown in FIG. 3. Specifically, a convolution transform output bit sequence u=[u₀, u₁, . . . , u_{N-2}, u_{N-1}] of length N is determined by the rate-profiling output bit sequence v, the generator polynomial g(D) (or equivalently the generator bit sequence g) and the polar matrix size N as follows, where vᵢ₋ₖ=0 for i<k.

```
For i = 0 to N-1
    uᵢ = 0;
    For k = 0 to m
      uᵢ = mod(uᵢ + gₖ·vᵢ₋ₖ, 2);
      End for
End for
```

Polar transform: The polar transform is the same as in the 5G polar coding. A polar transform output bit sequence d=[d₀, d₁, . . . , d_{N-2}, d_{N-1}] of length N is determined according to the convolution transform output bit sequence u and the polar matrix G^{(N)} as d=u·G^{(N)}, where the vector-matrix multiplication is over GF(2).

### INTRODUCTION TO EMBODIMENTS

This section discloses multiple examples related to rate matching for polar coding, PAC coding, or other pre-transformed polar coding with good performance.

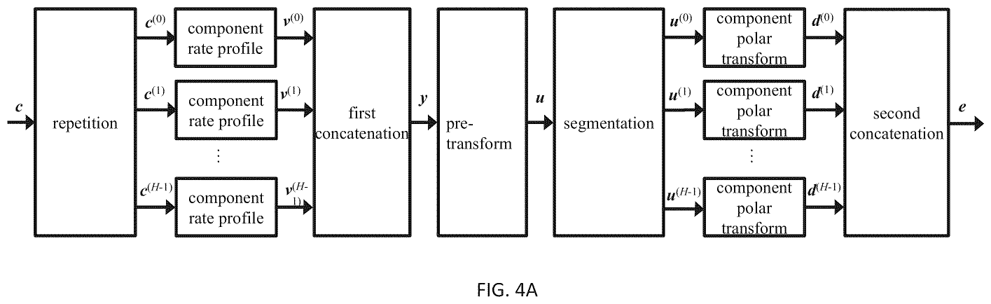

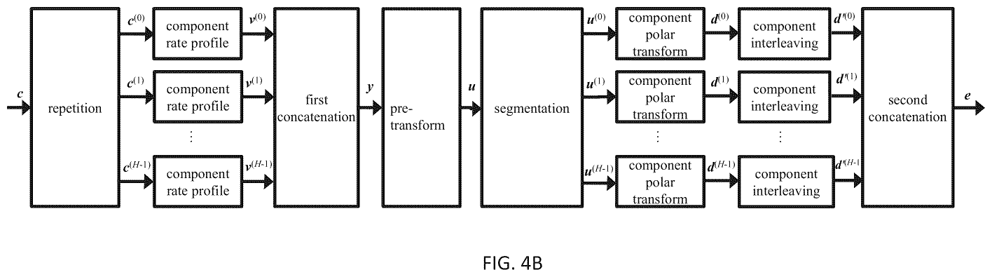

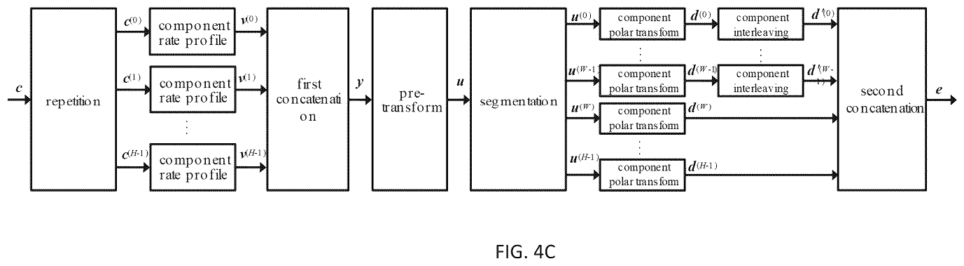

FIG. 4 shows diagrams of three example rate matching methods. The details of the examples will be explained in the following embodiments.

### Embodiment 1

This section discloses an encoding method used in a wireless communication system.

In one example, a method of digital communication comprising obtaining, by a first node, an input bit sequence c=[c₀, c₁, . . . , c_{K-1}]; and determining, by a first node, an output bit sequence having E bits based on an input bit sequence having K bits, wherein the output bit sequence is determined by performing a polar transform with H components and a pre-transform; wherein the polar transform is based on H polar matrices G^{(N}^{₀}⁾, G^{(N}^{₁}⁾, . . . , G^{(N}^{_{H−0}}⁾; and transmitting, by the first node, a signal including the output bit sequence e to a second node.

Here, K is the input length of the input bit sequence c.

E is the output length of the output bit sequence e.

H is the number of component polar matrices.

K, E, and H are all positive integers. In one example, K, E, and H satisfy K<E and H<E.

H is an integer greater than one.

For h=0, 1, . . . , H−1, the h-th component polar transform is based on the h-th component polar matrix G^{(N}^{ₕ}⁾, with Nₕ as the h-th component polar matrix size and Nₕ=2ⁿ^{ₕ} is a power of two, wherein nₕ is a non-negative integer.

In one example, the summation of H component polar matrix sizes is equal to the output length E, i.e., N₀+N₁+ . . . +N_{H-1}=E.

In another example, a method of digital communication may include obtaining, by a first node, an input bit sequence c=[c₀, c₁, . . . , c_{K-1}]; and determining, by the first node, an output bit sequence e=[e₀, e₁, . . . , e_{E-1}] by performing at least one of the following: a repetition, H component rate profiling, a first concatenation, a pre-transform, a segmentation, H component polar transform based on H polar matrices G^{(N}^{₀}⁾, G^{(N}^{₁}⁾, . . . , G^{(N}^{_{H−0}}⁾, W component interleaving, a second concatenation; and transmitting, by the first node, a signal including the output bit sequence e to a second node.

Here, K is the input length of the input bit sequence c; E is the output length of the output bit sequence e; H is the number of component polar matrices; W is the number of component interleaving.

In one example K, E, and H are positive integers and W is an integer not greater than H.

In another example, K, E, and H satisfy K<E and H<E.

H is an integer greater than one.

For h=0, 1, . . . , H−1, the h-th component polar transform is based on the h-th component polar matrix G^{(N}^{ₙ}⁾, wherein Nₕ is the h-th component polar matrix size and Nₕ=2ⁿ^{ₕ} is a power of two, wherein nₕ is a non-negative integer.

The summation of H component polar matrix sizes can be equal to the output length E, i.e., N₀+N₁+ . . . +N_{H-1}=E.

### Embodiment 2

This section discloses a decoding method used in a wireless communication system.

A method of digital communication, comprising receiving, by a second node, a signal including an output bit sequence e=[e₀, e₁, . . . , e_{E-1}] sent by a first node; and determining, by the second node, an estimation of an input bit sequence c=[c₀, c₁, . . . , c_{K-1}].

In one example, the output bit sequence e can be determined by determining by performing a polar transform with H components and a pre-transform; wherein the polar transform is based on H polar matrices G^{(N}^{₀}⁾, G^{(N}^{₁}⁾, . . . , G^{(N}^{_{H−0}}⁾, wherein E, K, H are integers greater than 1, wherein a polar matrix G^{(N}^{ᵢ}⁾ is of size Nᵢ.

In one example, the output bit sequence e can be determined by the first node by at least one of the following: a repetition, H component rate profiling, a first concatenation, a pre-transform, a segmentation, H component polar transform based on H polar matrices G^{(N}^{₀}⁾, G^{(N}^{₁}⁾, . . . , G^{(N}^{_{H−0}}⁾, W component interleaving, a second concatenation.

Here, K is the input length of the input bit sequence c; E is the output length of the output bit sequence e; H is the number of component polar matrices; W is the number of component interleaving; K, E, and H are positive integers; K<E and H<E; H is an integer greater than one; W is an integer not greater than H; for h=0, 1, . . . , H−1, the h-th component polar transform is based on the h-th component polar matrix G^{(N}^{ₕ}⁾, wherein Nₕ is the h-th component polar matrix size and Nₕ=2ⁿ^{ₕ} is a power of two, wherein nₕ is a non-negative integer; the summation of H component polar matrix sizes is equal to the output length E, i.e., N₀+N₁+ . . . +N_{H-1}=E.

### Embodiment 3

This section discloses the parameters related in determining the output bit sequence e.

Embodiment 3 is based on the above embodiments.

The output bit sequence e is determined by the first node by at least one of the following:
the output bit sequence length K,
the output bit sequence length E,
H component polar matrix sizes N₀, N₁, . . . , N_{H-1},
H component repetition lengths K₀, K₁, . . . , K_{H-1},
H component repetition index sets R⁽⁰⁾, R⁽¹⁾, . . . , R^{(H-1)}.
a first data bit index set Q={Q₀, Q₁, . . . , Q_{K-1}},
H component data bit index sets Q⁽⁰⁾, Q⁽¹⁾, . . . , Q^{(H-1)},
a generator polynomial g(D)=g₀+g₁·D+ . . . +gₘ₋₁·D^{m-1}+gₘ·D^{m} over GF(2),
a recursive feedback polynomial q(D)=q₀+q₁·D+q₂·D²+ . . . +qₘ·D^{m} over GF(2),
H component polar matrices G^{(N}^{₀}⁾, G^{(N}^{₁}⁾, . . . , G^{(N}^{_{H−0}}⁾,
W component interleaver pattern J⁽⁰⁾, J⁽¹⁾, . . . , J^{(W-1)},
wherein, K is the input sequence length; E is the output sequence length; H is the number of component polar matrices; m is a memory length or the degree of the generator polynomial g(D) or the degree of the recursive feedback polynomial q(D); W is the number of component interleaver patterns and W is a non-negative integer not greater than H; for h=0, 1, . . . , H−1, the h-th component repetition length Kₕ is a positive integer and the h-th component repetition length Kₕ is smaller than the h-th component polar matrix size Nₕ.
   H Component Polar Matrix Sizes N₀, N₁, . . . , N_{H-1}

For h=0, 1, . . . , H−1, the component polar matrix sizes Nₕ is the polar matrix size of the h-th component polar matrix G^{(N}^{ₕ}⁾.

In some embodiments, all H component polar matrix sizes N₀, N₁, . . . , N_{H-1} are the same, i.e., N₀=N₁= . . . =N_{H-1}. A specific example with H=3 polar matrix sizes for an output length E=24 is N₀=N₁=N₂=8.

In some embodiments, not all H component polar matrix sizes N₀, N₁, . . . , N_{H-1} are the same, i.e., there exists h≠k such that Nₕ≠Nₖ. A specific example with H=3 polar matrix sizes for an output length E=24 are N₀=16, N₁=4 and N₂=4, wherein N₀≠N₁.

In some embodiments, all H component polar matrix sizes N₀, N₁, . . . , N_{H-1} are different, i.e., if h≠k, Nₕ≠Nₖ. A first specific example with H=2 polar matrix sizes for an output length E=24 are N₀=16 and N₁=8, wherein N₀≠N₁. A second specific example with H=3 polar matrix sizes for an output length E=26 is N₀=16, N₁=8, and N₂=2, wherein N₀≠N₁, N₀≠N₂, and N₁≠N₂.

H Component Repetition Lengths K₀, K₁, . . . , K_{H-1}

In some embodiments, at least one of the H component repetition lengths K₀, K₁, . . . , K_{H-1} is equal to the input length K. A first specific example with H=3 polar matrix sizes and K=6, there are K₀=6, K₁=3 and K₂=1, wherein, K₀=K=6. A second specific example with H=3 polar matrix sizes and K=6, there are K₀=6, K₁=6 and K₂=1, wherein, K₀=K₁=K=6.

In some embodiments, all H component repetition lengths K₀, K₁, . . . , K_{H-1} are the same, i.e., K₀=K₁= . . . =K_{H-1}. A specific example with H=3 polar matrix sizes, there are K₀=K₁=K₂=2.

In some embodiments, not all H component repetition lengths K₀, K₁, . . . , K_{H-1} are the same, i.e., there exists h≠k such that Kₕ≠Kₖ. A specific example with H=3 polar matrix sizes, there are K₀=6, K₁=2 and K₂=2, wherein K₀≠K₁.

In some embodiments, all H component repetition lengths K₀, K₁, . . . , K_{H-1} are different, i.e., if h≠k, Kₕ≠Kₖ. A specific example with H=3 polar matrix sizes, there are K₀=6, K₁=3 and K₂=1, wherein K₀≠K₁, K₀≠K₂, and K₁≠K₂.

Component Repetition Index Sets R⁽⁰⁾, R⁽¹⁾, . . . , R^{(H-1)}

For h=0, 1, . . . , H−1, the h-th component repetition set R^{(h)}={R₀^{(h)}, R₁^{(h)}, . . . , R_{K}_{ₕ}₋₁^{(h)}} has Kₕ elements, i.e., the size of the h-th component repetition set is |R^{(h)}|=Kₕ, wherein Kₕ is the h-th component repetition length. For h=0, 1, . . . , H−1, the h-th component repetition index set R^{(h)}={R₀^{(h)}, R₁^{(R)}, . . . , R_{K}_{ₕ}₋₁^{(h)}} is a subset of a first-type integer set Z_{K}={0, 1, . . . , K−2, K−1}, wherein, the first-type integer set Z_{K}={0, 1, . . . , K−2, K−1} comprises all non-negative integers smaller than K.

In some embodiments, at least one of the H component repetition index sets R⁽⁰⁾, R⁽¹⁾, . . . , R^{(H-1)} is equal to a first-type integer set Z_{K}={0, 1, 2, . . . , K−1}, wherein the first-type integer set Z_{K}={0, 1, 2, . . . , K−1} comprises all non-negative integers smaller than K. In a specific example with K=6, E=24, H=2 polar matrix sizes N₀=16 and N₁=8, the H=2 component repetition index sets R⁽⁰⁾ and R⁽¹⁾ are R⁽⁰⁾=Z₆={0, 1, 2, 3, 4, 5} with K₀=K=6 and R⁽¹⁾={0, 1, 2} with K₁=3, respectively.

In some embodiments, none of H component repetition index sets R⁽⁰⁾, R⁽¹⁾, . . . , R^{(H-1)} is equal to a first-type integer set Z_{K}={0, 1, 2, . . . , K−1}, wherein the first-type integer set Z_{K}={0, 1, 2, . . . , K−1} comprises all non-negative integers smaller than K.

In a specific example with K=6, E=24, H=3 polar matrix sizes N₀=16, N₁=4 and N₂=4, the H=3 component repetition index sets are R⁽⁰⁾={0, 1, 2, 3, 4} with K₀=5, R⁽¹⁾={5, 0} with K₁=2, and R⁽²⁾={1, 2} with K₂=2, respectively, wherein R⁽⁰⁾≠Z₆, R⁽¹⁾≠Z₆, and, R⁽²⁾≠Z₆, wherein, Z₆={0, 1, 2, 3, 4, 5}.

In some embodiments, for h=0, 1, . . . , H−2, the (h+1)-th component repetition index set R^{(h+1)} is a subset of the h-th component repetition index set R^{(h)}={R₀^{(h)}, R₁^{(h)}, . . . , R_{K}_{ₕ}₋₁^{(h)}}, i.e., R^{(h+1)}⊆R^{(h)}. In a specific example with K=6, E=24, H=3 polar matrix sizes N₀=8, N₁=8, and N₂=8, the H=3 component repetition index sets R⁽⁰⁾, R⁽¹⁾, R⁽²⁾ are R⁽⁰⁾=Z₆={0, 1, 2, 3, 4, 5} with K₀=K=6, R⁽¹⁾={0, 1, 2} with K₁=3 and R⁽²⁾={0} with K₂=1, respectively, wherein, R⁽¹⁾⊆R⁽⁰⁾ and R⁽²⁾⊆R⁽¹⁾.

In some embodiments, for h, h′ being non-negative integers less than H and h not equal to h′, the intersection of the h-th component repetition index set R^{(h)} and the h′-th component repetition index set R^{(h′)} is an empty set, i.e., R^{(h)}∩R^{(h′)}=Φ={ }, wherein Φ denotes the empty set. In a specific example with K=6, E=24, H=3 polar matrix sizes N₀=16, N₁=4 and N₂=4, the H=3 component repetition index sets are R⁽⁰⁾={0, 1} with K₀=2, R⁽¹⁾={2, 3} with K₁=2, and R⁽²⁾={4, 5} with K₁=2, respectively.

In some embodiments, there exists h and k being non-negative integers less than H and h not equal to k (h≠k) such that the intersection of the h-th component repetition index set R^{(h)} and the k-th component repetition index set R^{(k)} is not an empty set, i.e., R^{(h)}∩(R^{(k)}≠Φ, wherein, Φ={ } is the empty set.

In a first specific example with K=6, E=24, H=2 polar matrix sizes N₀=16 and N₁=8, the H=2 component repetition index sets R⁽⁰⁾ and R⁽¹⁾ are R⁽⁰⁾=Z₆={0, 1, 2, 3, 4, 5} with K₀=K=6 and R⁽¹⁾={0, 1, 2} with K₁=3, respectively, wherein, R⁽⁰⁾∩(R⁽¹⁾={0, 1, 2}≠{ }=Φ; wherein Φ denotes the empty set.

In a second specific example with K=6, E=24, H=3 polar matrix sizes N₀=8, N₁=8, and N₂=8, the H=3 component repetition index sets R⁽⁰⁾, R⁽¹⁾, R⁽²⁾ are R⁽⁰⁾=Z₆={0, 1, 2, 3, 4, 5} with K₀=K=6, R⁽¹⁾={0, 1, 2} with K₁=3 and R⁽²⁾={4} with K₂=1, respectively, wherein, R⁽⁰⁾∩R⁽¹⁾={0, 1, 2}≠Φ and R⁽⁰⁾∩R⁽²⁾={4}≠Φ; wherein Φ denotes the empty set.

In a third specific example with K=6, E=26, H=3 polar matrix sizes N₀=16, N₁=8, and N₂=2, the H=3 component repetition index sets R⁽⁰⁾, R⁽¹⁾, R⁽²⁾ are R⁽⁰⁾={0, 1, 2, 3, 4} with K₀=5, R⁽¹⁾={5, 0} with K₁=2, and R⁽²⁾={4} with K₂=1, respectively, wherein, R⁽⁰⁾∩R⁽¹⁾={0}≠Φ and R⁽⁰⁾∩R⁽²⁾={4}≠Φ; wherein Φ denotes the empty set.

In some embodiments, all H component repetition index sets R⁽⁰⁾, R⁽¹⁾, . . . , R^{(H-1)} comprise an index k, wherein k is a non-negative integer. A specific example with H=3 component repetition index sets R⁽⁰⁾, R⁽¹⁾, R⁽²⁾ are R⁽⁰⁾={0, 1, 2, 3, 4} with K₀=5, R⁽¹⁾={5, 0, 2} with K₁=2, and R⁽²⁾={4, 0} with K₂=2, respectively, wherein H=3 component repetition index sets R⁽⁰⁾, R⁽¹⁾, R⁽²⁾ comprise an index k=0.

Component Data Bit Index Sets Q⁽⁰⁾, Q⁽¹⁾, . . . , Q^{(H-1)}

For h=0, 1, . . . , H−1, the h-th component data bit index set Q^{(h)}={Q₀^{(h)}, Q₁^{(h)}, . . . , Q_{K}_{ₕ}₋₁^{(h)}} has Kₕ elements, i.e., the size of the h-th component data bit index set is |Q^{(h)}|=Kₕ, wherein Kₕ is the h-th component repetition length. For h=0, 1, . . . , H−1, the h-th component data bit index set Q^{(h)}={Q₀^{(h)}, Q₁^{(h)}, . . . , Q_{K}_{ₕ}₋₁^{(h)}} i is a subset of an h-th second-type integer set Z_{N}_{ₕ}={0, 1, . . . , Nₕ−2, Nₕ−1}, wherein, Nₕ is the h-th polar matrix size and the h-th second-type integer set Z_{N}_{ₕ}={0, 1, . . . , Nₕ−2, Nₕ−1} comprises all non-negative integers smaller than Nₕ. For h=0, 1, . . . , H−1, elements in the h-th data bit index set Q^{(h)} are non-negative integers smaller than the polar matrix size Nₕ of the h-th component polar matrix G^{(N}^{ₕ}⁾.

In some embodiments, for some h, if k<k′, the k-th element Qₖ^{(h)} in the h-th component data bit index set Q^{(h)} is smaller than the k′-th element Q_{k′}^{(h)} in the h-th component data bit index set Q^{(h)}, i.e., the h-th component data bit index set Q^{(h)} is sorted in ascending order according to index values with Q₀<Q₁< . . . <Q_{K-2}<Q_{K-1}. In some embodiments, for some h, if k<k′, the k-th element Qₖ^{(h)} in the h-th component data bit index set Q^{(h)} is greater than the k′-th element Q_{k′}^{(h)} in the h-th component data bit index set Q^{(h)}, i.e., the h-th component data bit index set Q^{(h)} is sorted in descending order according to index values with Q₀>Q₁> . . . >Q_{K-2}>Q_{K-1}. In some embodiments, for some h, if k<k′, the reliability of the Qₖ^{(h)}-th polarized sub-channel (denoted as W(Qₖ^{(h)})) corresponding to the h-th component polar matrix G^{(N}^{ₕ}⁾ is smaller than the reliability of the Q_{k′}^{(h)}-th polarized sub-channel (denoted as W(Q_{k′}^{(h)})) corresponding to the h-th component polar matrix G^{(N}^{ₕ}⁾, i.e., the h-th component data bit index set Q^{(h)} is sorted in ascending order according to the polarized sub-channel reliability with W(Q₀^{(h)})<W(Q₁^{(h)})< . . . <W(Q_{K}_{ₕ}₋₂^{(h)})<W(Q_{K}_{ₕ}₋₁^{(h)}). In some embodiments, for some h, if k<k′, the reliability of the Qₖ^{(h)}-th polarized sub-channel (denoted as W(Qₖ^{(h)}) corresponding to the h-th component polar matrix G^{(N}^{ₕ}⁾ is greater than the reliability of the Q_{k′}^{(h)}-th polarized sub-channel (denoted as W(Q_{k′}^{(h)})) corresponding to the h-th component polar matrix G^{(N}^{ₕ}⁾, i.e., the h-th component data bit index set Q^{(h)} is sorted in descending order according to the polarized sub-channel reliability with W(Q₀^{(h)}>W(Q₁^{(h)}> . . . >W(Q_{K}_{ₕ}₋₂^{(h)})<W(Q_{K}_{ₕ}₋₁^{(h)}).

In some embodiments, at least one of the H component data bit index set sizes K₀, K₁, . . . , K_{H-1} is equal to the input length K.

In a first specific example with K=6, E=24, H=2 polar matrix sizes N₀=16 and N₁=8, the H=2 component data bit index sets Q⁽⁰⁾ and Q⁽¹⁾ are Q⁽⁰⁾={12, 7, 11, 13, 14, 15} with K₀=K=6 and Q⁽¹⁾={12, 7, 11} with K₁=3, respectively, wherein, the 0-th component data bit index set Q⁽⁰⁾={12, 7, 11, 13, 14, 15} is corresponding to the 0-th component polar matrix G^{(N}^{₀}⁾=G⁽¹⁶⁾ and the 1^{st} component data bit index set Q⁽¹⁾={5, 6, 7} is corresponding to the 1^{st} component polar matrix G^{(N}^{₁}⁾=G⁽⁸⁾.

In a second specific example with K=6, E=24, H=3 polar matrix sizes N₀=8, N₁=8, and N₂=8, the H=3 component data bit index sets Q⁽⁰⁾, Q⁽¹⁾, Q⁽²⁾ are Q⁽⁰⁾={2, 4, 3, 5, 6, 7} with K₀=K=6, Q⁽¹⁾={2, 4, 5} with K₁=3 and Q⁽²⁾={3} with K₂=1, respectively. In a third specific example with K=6, E=26, H=3 polar matrix sizes N₀=16, N₁=8, and N₂=2, the H=3 component repetition index sets Q⁽⁰⁾, Q⁽¹⁾, Q⁽²⁾ are Q⁽⁰⁾={7, 11, 13, 14, 15} with K₀=5, Q⁽¹⁾={6, 7} with K₁=2, and Q⁽²⁾={1} with K₂=1, respectively.

### First Data Bit Index Set Q

The first data bit index set Q={Q₀, Q₁, . . . , Q_{K-1}} has K elements, i.e., the size of the input data bit index set is |Q|=K, wherein K is the input length. The first data bit index set Q={Q₀, Q₁, . . . , Q_{K-1}} is a subset of a third-type integer set Z_{N}_{ₘ}={0, 1, . . . , Nₘ−2, Nₘ−1}, wherein, Nₘ is the maximum value among the H polar matrix sizes N₀, N₁, . . . , N_{H-1}, i.e.,

$${N}_{m} = {max}_{0 \leq h < H} {N}_{h}$$

and the third-type integer set Z_{N}_{ₘ}={0, 1, . . . , Nₘ−2, Nₘ−1} comprises all non-negative integers smaller than Nₘ. In some embodiments, at least one of the H component data bit index sets Q⁽⁰⁾, Q⁽¹⁾, . . . , Q^{(H-1)} is equal to the first data bit index set Q={Q₀, Q₁, . . . , Q_{K-1}}.

In a first specific example with K=6, Nₘ=16, and E=24, a first data bit index set is Q={12, 7, 11, 13, 14, 15}.

In a second specific example with K=6 and H=3 polar matrix sizes N₀=8, N₁=8 and N₂=8, we have Nm=max(max(N₀, N₁), N₂)=8, a data bit index set Q={2, 4, 3, 5, 6, 7}, and H=3 component data bit index set Q⁽⁰⁾={Q₀⁽⁰⁾, Q₁⁽⁰⁾, Q₂⁽⁰⁾, Q₃⁽⁰⁾, Q₄⁽⁰⁾, Q₅⁽⁰⁾}=Q={2, 4, 3, 5, 6, 7}, Q⁽¹⁾={Q₀⁽¹⁾, Q₁⁽¹⁾, Q₂⁽¹⁾}={2, 4, 3}, Q⁽²⁾={Q₀⁽²⁾}={4}.

In a third specific example with K=6 and H=3 polar matrix sizes N₀=16, N₁=8 and N₂=2, we have Nₘ=max(max(N₀, N₁), N₂)=16, and a data bit index set Q={12, 7, 11, 13, 14, 15}.

In some embodiments, for k=0, 1, . . . , K−2, the element Qₖ in the first data bit index set Q is smaller than Qₖ₊₁, i.e., the first data bit index set Q is sorted in ascending order according to index values with Q₀<Q₁< . . . <Q_{K-2}<Q_{K-1}.

In some embodiments, for k=0, 1, . . . , K−2, the reliability of the Qₖ-th polarized sub-channel (denoted as W(Qₖ)) is smaller than the reliability of the Qₖ₊₁-th polarized sub-channel (denoted as W(Qₖ₊₁)), i.e., the first data bit index set Q is sorted in ascending order according to the polarized sub-channel reliability with W(Q₀)<W(Q₁)< . . . <W(Q_{K-2})<W(Q_{K-1}).

In a first specific example with Nₘ=8 and K=4, a first data bit index set is Q={Q₀, Q₁, Q₂, Q₃}={3, 5, 6, 7} with Q₀<Q₁<Q₂<Q₃.

In a second specific example with Nₘ=32 and K=25, a first data bit index set is Q={Q₀, Q₁, Q₂, Q₃, Q₄, Q₅, Q₆, Q₇, Q₈, Q₉, Q₁₀, Q₁₁, Q₁₂, Q₁₃, Q₁₄, Q₁₅, Q₁₆, Q₁₇, Q₁₈, Q₁₉, Q₂₀, Q₂₁, Q₂₂, Q₂₃, Q₂₄}={5, 9, 6, 17, 10, 18, 12, 20, 24, 7, 11, 19, 13, 14, 21, 26, 25, 22, 28, 15, 23, 31, 27, 29, 30} with polarized sub-channel reliability being W(Q₀)<W(Q₁)<W(Q₂)<W(Q₃)<W(Q₄)<W(Q₅) <W(Q₆)<W(Q₇)<W(Q₈)<W(Q₉)<W(Q₁₀)<W(Q₁₁)<W(Q₁₂)<W(Q₁₃)<W(Q₁₄)<W(Q₁₅)<W(Q₁₆)<W(Q₇₁)<W(Q₁₈)<W(Q₁₉)<W(Q₂₀)<W(Q₂₁)<W(Q₂₂)<W(Q₂₃)<W(Q₂₄).

A Generator Polynomial g(D)

The generator polynomial g(D)=g₀+g₁·D+ . . . +gₘ·D^{m} can be any binary polynomial over GF(2), wherein h is the memory length of the generator polynomial g(D) or the degree of generator polynomial g(D). A generator polynomial g(D)=g₀+g₁·D+ . . . +gₘ·D^{m} has a corresponding generator bit sequence g=[g₀, g₁, . . . , gₘ] of length m+1. The generator polynomial g(D) and its corresponding generator bit sequence g are used interchangeably in this document.

In a first specific example with a memory length m=6, a generator polynomial g(D)=g₀+g₁·D + . . . +gₘ·D^{m}=g₀+g₁·D+g₂·D²+g₃·D³+g₄·D⁴+g₅·D⁵+g₆·D⁶=1+D²+D³+D⁵+D⁶. In a second specific example with a memory length m=3, a generator polynomial g(D)=g₀+g₁·D+ . . . +gₘ·D^{m}=g₀+g₁·D+g₂·D²+g₃·D³=1+D+D³.

More specific examples for a generator polynomial g(D)=g₀+g₁·D+ . . . +gₘ·D^{m} are as follows:

$$1. For m = 1 , g ( D ) = {g}_{0} + {g}_{1} \cdot D + … + {g}_{m} \cdot {D}^{m} = {g}_{0} + {g}_{1} \cdot D = 1 + D ;$$

$$2. For m = 2 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} = 1 + {D}^{2} ; \\ 3. For m = 3 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + {g}_{3} \cdot {D}^{3} = 1 + D + {D}^{2} + {D}^{3} ; \\ 4. For m = 4 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + {g}_{3} \cdot {D}^{3} + {g}_{4} \cdot {D}^{4} = 1 + D + {D}^{2} + {D}^{4} and g ( D ) = {g}_{0} + {g}_{1} \cdot D + … + {g}_{m} \cdot {D}^{m} = {g}_{0} + {g}_{1} \cdot D + {g}_{2} \cdot {D}^{2} + {g}_{3} \cdot {D}^{3} + {g}_{4} \cdot {D}^{4} = 1 + {D}^{2} + {D}^{3} + {D}^{4} ; \\ 5. For m = 5 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{5} \cdot {D}^{5} = 1 + D + {D}^{3} + {D}^{5} and g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{5} \cdot {D}^{5} = 1 + {D}^{2} + {D}^{4} + {D}^{5} ; \\ 6. For m = 6 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{6} \cdot {D}^{6} = 1 + {D}^{6} ; \\ 7. For m = 7 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{7} \cdot {D}^{7} = 1 + {D}^{3} + {D}^{5} + {D}^{7} and g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{7} \cdot {D}^{7} = 1 + {D}^{2} + {D}^{4} + {D}^{7} ; \\ 8. For m = 8 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{8} \cdot {D}^{8} = 1 + {D}^{4} + {D}^{8} ; \\ 9. For m = 9 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{9} \cdot {D}^{9} = 1 + {D}^{3} + {D}^{4} + {D}^{5} + {D}^{7} + {D}^{9} and g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{9} \cdot {D}^{9} = 1 + {D}^{2} + {D}^{4} + {D}^{5} + {D}^{6} + {D}^{9} ; \\ 10. For m = 10 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{10} \cdot {D}^{10} = 1 + {D}^{2} + {D}^{6} + {D}^{7} + {D}^{10} and g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{10} \cdot {D}^{10} = 1 + {D}^{3} + {D}^{4} + {D}^{8} + {D}^{10} ; \\ 11. For m = 11 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{11} \cdot {D}^{11} = 1 + D + {D}^{2} + {D}^{4} + {D}^{8} + {D}^{10} + {D}^{11} and g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{11} \cdot {D}^{11} = 1 + D + {D}^{3} + {D}^{7} + {D}^{9} + {D}^{10} + {D}^{11} ; \\ 12. For m = 12 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{12} \cdot {D}^{12} = 1 + {D}^{2} + {D}^{5} + {D}^{6} + {D}^{7} + {D}^{8} + {D}^{9} + {D}^{10} + {D}^{11} + {D}^{12} and g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{12} \cdot {D}^{12} = 1 + D + {D}^{2} + {D}^{3} + {D}^{4} + {D}^{5} + {D}^{6} + {D}^{7} + {D}^{10} + {D}^{12} ; \\ 13. For m = 13 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{13} \cdot {D}^{13} = 1 + D + {D}^{4} + {D}^{5} + {D}^{9} + {D}^{10} + {D}^{13} and g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{13} \cdot {D}^{13} = 1 + {D}^{3} + {D}^{4} + {D}^{8} + {D}^{9} + {D}^{12} + {D}^{13} ; \\ 14. For m = 14 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{14} \cdot {D}^{14} = 1 + D + {D}^{2} + {D}^{7} + {D}^{8} + {D}^{10} + {D}^{12} + {D}^{14} and g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{14} \cdot {D}^{14} = 1 + {D}^{2} + {D}^{4} + {D}^{6} + {D}^{7} + {D}^{12} + {D}^{13} + {D}^{14} ; \\ 15. For m = 15 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{15} \cdot {D}^{15} = 1 + D + {D}^{4} + {D}^{6} + {D}^{7} + {D}^{8} + {D}^{9} + {D}^{15} and g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{15} \cdot {D}^{15} = 1 + {D}^{6} + {D}^{7} + {D}^{8} + {D}^{9} + {D}^{11} + {D}^{14} + {D}^{15} ; \\ 16. For m = 16 , g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{16} \cdot {D}^{16} = 1 + {D}^{2} + {D}^{4} + {D}^{6} + {D}^{8} + {D}^{13} + {D}^{14} + {D}^{16} and g ( D ) = {g}_{0} + {g}_{1} \cdot D + … + {g}_{m} \cdot {D}^{m} = {g}_{0} + {g}_{1} \cdot D + {g}_{2} \cdot {D}^{2} + … + {g}_{16} \cdot {D}^{16} = 1 + {D}^{2} + {D}^{3} + {D}^{8} + {D}^{10} + {D}^{12} + {D}^{14} + {D}^{16} ;$$

wherein m is the memory length.
A Recursive Feedback Polynomial q(D)

The recursive feedback polynomial q(D)=q₀+q₁·D+ . . . +qₘ·D^{m} can be any binary polynomial over GF(2), wherein m is the memory length of the recursive feedback polynomial q(D) or the degree of the recursive feedback polynomial q(D). A recursive feedback polynomial q(D)=q₀+q₁·D+ . . . +qₘ·D^{m} has a corresponding recursive feedback bit sequence q=[q₀, q₁, . . . , qₘ] of length m+1. The recursive feedback polynomial q(D) and its corresponding recursive feedback bit sequence q are used interchangeably in this document.

In some embodiments, the value of q₀ is a bit one “1” in the recursive feedback polynomial q(D).

In a first specific example with a memory length m=6, a recursive feedback polynomial is q(D)=q₀+q₁·D+ . . . +qₘ·D^{m}=q₀+q₁·D+q₂·D²+q₃·D³+q₄·D⁴+q₅·D⁵+q₆·D⁶=1+D²+D⁴+D⁵+D⁶.

In a second specific example with a memory length m=3, a recursive feedback polynomial is q(D)=q₀+q₁·D+ . . . +qₘ·D^{m}=q₀+q₁·D+q₂·D²+q₃·D³=1+D²+D³.

Component Interleaver Patterns J⁽⁰⁾, J⁽¹⁾, . . . , J^{(W-1)}

For h=0, 1, . . . , W−1, the h-th component interleaver pattern J^{(h)}=[J₀^{(h)}, J₁^{(h)}, . . . , J_{N}_{ₕ}₋₁^{(h)}] is of size Nₕ, wherein, Nₕ is the h-th polar matrix size and J^{(h)} is a permutation of the sequence [0, 1, 2, . . . , Nₕ−1].

A first specific example with H=2, W=2, N₀=16, N₁=8, a 0-th component interleaver pattern J⁽⁰⁾=[J₀⁽⁰⁾, J₁⁽⁰⁾, . . . , J_{N}_{₀}₋₁⁽⁰⁾]=[J₀⁽⁰⁾, J₁⁽⁰⁾, J₂⁽⁰⁾, J₃⁽⁰⁾, J₄⁽⁰⁾, J₅⁽⁰⁾, J₆⁽⁰⁾, J₇⁽⁰⁾, J₈⁽⁰⁾, J₉⁽⁰⁾, J₁₀⁽⁰⁾, J₁₁⁽⁰⁾, J₁₂⁽⁰⁾, J₁₃⁽⁰⁾, J₁₄⁽⁰⁾, J₁₅⁽⁰⁾]=[0, 1, 2, 4, 3, 5, 6, 7, 8, 9, 10, 11, 13, 12, 14, 15] is a permutation of the array [0, 1, 2, 3, 4, 5, 6, 7, 8, 9, 10, 11, 12, 13, 14, 15] and a 1st component interleaver pattern J⁽¹⁾=[J₀⁽¹⁾, J₁⁽¹⁾, . . . , J_{N}_{₁}₋₁⁽¹⁾]=[J₀⁽¹⁾, J₁⁽¹⁾, J₂⁽¹⁾, J₃⁽¹⁾, J₄⁽¹⁾, J₅⁽¹⁾, J₆⁽¹⁾, J₇⁽¹⁾]=[0, 1, 2, 4, 3, 5, 6, 7] is a permutation of the array [0, 1, 2, 3, 4, 5, 6, 7].

A second specific example with H=3, W=2, N₀=N₁=N₂=8, a 0-th component interleaver pattern J⁽⁰⁾=[J₀⁽⁰⁾, J₁⁽⁰⁾, . . . , J_{N}_{₀}₋₁⁽⁰⁾]=[J₀⁽⁰⁾, J₁⁽⁰⁾, J₂⁽⁰⁾, J₃⁽⁰⁾, J₄⁽⁰⁾, J₅⁽⁰⁾, J₆⁽⁰⁾, J₇⁽⁰⁾]=[0, 1, 2, 3, 4, 6, 7, 5] is a permutation of the array [0, 1, 2, 3, 4, 5, 6, 7] and a 1^{st} component interleaver pattern J⁽¹⁾=[J₀⁽¹⁾, J₁⁽¹⁾, . . . , J_{N}_{₁}₋₁⁽¹⁾]=J₀⁽¹⁾, J₁⁽¹⁾, J₂⁽¹⁾, J₃⁽¹⁾, J₄⁽¹⁾, J₅⁽¹⁾, J₆⁽¹⁾, J₇⁽¹⁾=[0, 1, 2, 4, 3, 5, 6, 7] is a permutation of the array [0, 1, 2, 3, 4, 5, 6, 7].

A third specific example with H=3, W=3, N₀=16, N₁=8, and N₂=2, a 0-th component interleaver pattern J⁽⁰⁾=[J₀⁽⁰⁾, J₁⁽⁰⁾, . . . , J_{N}_{₀}₋₁⁽⁰⁾]=[J₀⁽⁰⁾, J₁⁽⁰⁾, J₂⁽⁰⁾, J₃⁽⁰⁾, J₄⁽⁰⁾, J₅⁽⁰⁾, J₆⁽⁰⁾, J₇⁽⁰⁾, J₈⁽⁰⁾, J₉⁽⁰⁾, J₁₀⁽⁰⁾, J₁₁⁽⁰⁾, J₁₂⁽⁰⁾, J₁₃⁽⁰⁾, J₁₄⁽⁰⁾, J₁₅⁽⁰⁾]=[0, 1, 2, 4, 3, 5, 6, 7, 8, 9, 10, 11, 12, 13, 14, 15] is a permutation of the array [0, 1, 2, 3, 4, 5, 6, 7, 8, 9, 10, 11, 12, 13, 14, 15], a 1^{st} component interleaver pattern J⁽¹⁾=[J₀⁽¹⁾, J₁⁽¹⁾, . . . , J_{N}_{₁}₋₁⁽¹⁾]=[J₀⁽¹⁾, J₁⁽¹⁾, J₂⁽¹⁾, J₃⁽¹⁾, J₄⁽¹⁾, J₅⁽¹⁾, J₆⁽¹⁾, J₇⁽¹⁾]=[5, 4, 7, 1, 6, 0, 2, 3] is a permutation of the array [0, 1, 2, 3, 4, 5, 6, 7], and a 2^{nd} component interleaver pattern J⁽²⁾=[J₀⁽²⁾, J₁⁽²⁾, . . . , J_{N}_{₂}₋₁⁽²⁾]=[J₀⁽²⁾, J₁⁽²⁾]=[1, 0] is a permutation of the array [0, 1].

A fourth specific example with H=3, W=1, N₀=8, N₁=16, and N₂=2, a 2^{nd} component interleaver pattern J⁽²⁾=[J₀⁽²⁾, J₁⁽²⁾, . . . , J_{N}_{₂}₋₁⁽²⁾]=[J₀⁽²⁾, J₁⁽²⁾]=[1, 0] is a permutation of the array [0, 1].

FIG. 4A shows a first example for rate matching pre-transformed polar coding with a repetition and a single pre-transform, wherein there is no component interleaver patterns.

FIG. 4B shows a second example for rate matching pre-transformed polar coding with a repetition and a single pre-transform, wherein the number of component interleaver patterns is equal to the number of component matrices.

FIG. 4C shows a third example for rate matching pre-transformed polar coding with a repetition and a single pre-transform, wherein the number of component interleaver patterns is smaller than the number of component matrices.

In some embodiments, the first node performs a repetition by obtaining the input bit sequence c of length K and determining H component repetition output bit sequences c⁽⁰⁾, c⁽¹⁾, c⁽²⁾, . . . , c^{(H-1)}, wherein, for h=0, 1, 2, . . . , H−1, the h-th component repetition output bit sequence c^{(h)}=[c₀^{(h)}, c₁^{(h)}, . . . , c_{K}_{ₕ}₋₁^{(h)}] is of length Kₕ.

In some embodiments, for h=0, 1, 2, . . . , H−1, the first node performs a component rate profiling by obtaining the h-th component repetition output bit sequences c^{(h)}=[c₀^{(h)}, c₁^{(h)}, . . . , c_{K}_{ₕ}₋₁^{(h)}] and determining a component rate profiling output bit sequence v^{(h)}=[v₀^{(h)}, v₁^{(h)}, . . . , v_{N}_{ₕ}₋₁^{(h)}] of length Nₕ, wherein Nₕ is the polar matrix size of the h-th component polar matrix G^{(N}^{ₕ}⁾.

In some embodiments, the first node performs a first concatenation by obtaining H component rate profiling output bit sequences v⁽⁰⁾, v⁽¹⁾, v⁽²⁾, . . . , v^{(H-1)} and determining a concatenation output bit sequence y=[y₀, y₁, y₂, . . . , Y_{E-1}] of length E, wherein, for h=0, 1, . . . , H−1, the h-th component rate profiling output bit sequence v^{(h)}=[v₀^{(h)}, v₁^{(h)}, . . . , v_{N}_{ₕ}₋₁^{(h)}] is of length Nₕ; E=N₀+N₁+ . . . +N_{H-1} is the length of the output bit sequence e=[e₀, e₁, e₂, . . . , e_{E-1}], wherein, Nₕ is the polar matrix size of the h-th component polar matrix G^{(N}^{ₕ}⁾.

In some embodiments, the first node performs a pre-transform by obtaining the concatenation output bit sequence y=[y₀, y₁, y₂, . . . , Y_{E-1}] of length E and determining a pre-transform output bit sequence u=[u₀, u₁, u₂, . . . , u_{E-1}] of length E by at least one of the following: the generator polynomial g(D)=g₀+g₁·D+g₂·D²+ . . . +gₘ·D^{m} over GF(2), the recursive feedback polynomial q(D)=q₀+q₁·D+q₂·D²+ . . . +qₘ·D^{m} over GF(2), wherein, E is the length of the output bit sequence e=[e₀, e₁, e₂, . . . , e_{E-1}].

In some embodiments, the first node performs a segmentation by obtaining the pre-transform output bit sequence u=[u₀, u₁, u₂, . . . , u_{E-1}] of length E and determining H segmentation output bit sequences u⁽⁰⁾, u⁽¹⁾, . . . , u^{(H-1)} according to H component polar matrix sizes N₀, N₁, . . . , N_{H-1}, wherein, H is the number of component polar matrices; for h=0, 1, . . . , H−1, the h-th segmentation output bit sequence u^{(h)} is of length Nₕ, wherein Nₕ is the h-th component polar matrix size and E is the length of the output bit sequence e=[e₀, e₁, e₂, . . . , e_{E-1}].

In some embodiments, for h=0, 1, 2, . . . , H−1, the first node performs a component polar transform by obtaining the h-th segmentation output bit sequence u^{(h)} of length Nₕ and determining an h-th component polar transform output bit sequence d^{(h)}=[d₀^{(h)}, d₁^{(h)}, . . . , d_{N}_{ₕ}₋₁^{(h)}] of length Nₕ according to the h-th component polar matrix G^{(N}^{ₕ}⁾ as d^{(h)}=u^{(h)}·G^{(N}^{ₕ}⁾, wherein, d^{(h)}=u^{(h)}·G^{(N}^{ₕ}⁾ is the component polar transform, which is a vector-matrix multiplication of the h-th segmentation output bit sequence u^{(h)} of length Nₕ and the component polar matrix G^{(N}^{ₕ}⁾over GF(2) to obtain h-th component polar transform output bit sequence d^{(h)}=[d₀^{(h)}, d₁^{(h)}, . . . , d_{N}_{ₕ}₋₁^{(h)}].

Three examples are shown in FIGS. 4A to 4C.

In some embodiments, the first node performs a second concatenation by obtaining the H component polar transform output bit sequences d⁽⁰⁾, d⁽¹⁾, d⁽²⁾, . . . , d^{(H-1)} and determining the output bit sequence e=[e₀, e₁, . . . , e_{E-1}] of length E, wherein, a specific example is shown in FIG. 4A.

In some embodiments, the number of interleaver patterns W is equal to the number of component polar matrices H and for h=0, 1, 2, . . . , H−1, the first node performs a component interleaving by obtaining the h-th component polar transform output bit sequence d^{(h)}=[d₀^{(h)}, d₁^{(h)}, . . . , d_{N}_{ₕ}₋₁^{(h)}] of length Nₕ and determining an h-th component interleaving output bit sequence d′^{(h)}=[d′₀^{(h)}, d′₁^{(h)}, . . . , d′_{N}_{ₕ}₋₁^{(h)}] of length Nₕ, wherein Nₕ is the polar matrix size of G^{(N}^{ₕ}⁾. In some embodiments, the first node performs a second concatenation by obtaining the H component interleaving output bit sequences d′⁽⁰⁾, d′⁽¹⁾, d′⁽²⁾, . . . , d′^{(H-1)} and determining the output bit sequence e=[e₀, e₁, . . . , e_{E-1}] of length E, wherein, a specific example is shown in FIG. 4B.

In some embodiments, the number of interleaver patterns W is smaller than the number of component polar matrices H and for h=0, 1, 2, . . . , W−1, the first node performs a component interleaving by obtaining the h-th component polar transform output bit sequence d^{(h)}=[d₀^{(h)}, d₁^{(h)}, . . . , d_{N}_{ₕ}₋₁^{(h)}] of length Nₕ and determining an h-th component interleaving output bit sequence d′^{(h)}=[d′₀^{(h)}, d′₁^{(h)}, . . . , d′_{N}_{ₕ}₋₁^{(h)}] of length Nₕ, wherein Nₕ is the polar matrix size of G^{(N}^{ₕ}⁾. In some embodiments, the first node performs a second concatenation by obtaining the W component interleaving output bit sequences d′⁽⁰⁾, d′⁽¹⁾, d′⁽²⁾, . . . , d′^{(W-1)} the H−W component polar transform output bit sequences d^{(W)}, d^{(W+1)}, . . . , d^{(H-1)} then determining the output bit sequence e=[e₀, e₁, . . . , e_{E-1}] of length E, wherein, a specific example is shown in FIG. 4C.

In some embodiments, the first node performs a component interleaving on W bit sequences of the H component polar transform output bit sequences d⁽⁰⁾, d⁽¹⁾, d⁽²⁾, . . . , d^{(H-1)} to determine W component interleaving output bit sequences, wherein W is a non-negative integer not greater than H. In a first specific example with H=3 component polar transform output bit sequences d⁽⁰⁾, d⁽¹⁾, d⁽²⁾ and W=2, the first node performs a component interleaving on W=2 component polar transform output bit sequences d⁽⁰⁾, d⁽²⁾ to determine W=2 component interleaving output bit sequences d′⁽⁰⁾, d′⁽²⁾, wherein the 0-th component interleaving output bit sequence d′⁽⁰⁾ is corresponding to the 0-th component polar transform output bit sequence d⁽⁰⁾; the 2^{nd} component interleaving output bit sequence d′⁽²⁾ is corresponding to the 2^{nd} component polar transform output bit sequence d⁽²⁾.

In a second specific example with H=3 component polar transform output bit sequences d⁽⁰⁾, d⁽¹⁾, d⁽²⁾ and W=1, the first node performs a component interleaving on W=1 component polar transform output bit sequence d⁽⁰⁾ to determine W=1 component interleaving output bit sequence d′⁽⁰⁾, wherein the 1^{st} component interleaving output bit sequence d′⁽⁰⁾ is corresponding to the 1^{st} component polar transform output bit sequence d⁽⁰⁾.

### Embodiment 4

This section discloses examples involving repetition.

Embodiment 4 is based on the above embodiments.

FIGS. 4A to 4C shows three specific example for the repetition. In some embodiment, the repetition comprises obtaining, by the first node, a repetition input bit sequence; and determining, by the first node, H component repetition output bit sequences c⁽⁰⁾, c⁽¹⁾, c⁽²⁾, . . . , c^{(H-1)} by at least one of the following: the H component repetition lengths K₀, K₁, . . . , K_{H-1}, the H component repetition index sets R⁽⁰⁾, R⁽¹⁾, . . . , R^{(H-1)}.

Here, the repetition input bit sequence can be an input bit sequence c=[c₀, c₁, . . . , c_{K-1}] of length K; for h=0, 1, . . . , H−1, the h-th component repetition output bit sequence c^{(h)}=[c₀^{(h)}, c₁^{(h)}, . . . , c_{K}_{ₕ}₋₁^{(h)}] is of length Kₕ.

In some embodiments, for h=0, 1, . . . , H−1, the repetition determines the h-th component repetition output bit sequence c^{(h)} by setting the k-th bit cₖ^{(h)} in the h-th component repetition output bit sequence c^{(h)} to the bit with an index Rₖ^{(h)} in the input bit sequence c=[c₀, c₁, . . . , c_{K-1}], i.e., cₖ^{(h)}=c_{R}_{ₖ}_{^{(h)}}, wherein a pseudo-code is as follows.

```
For h = 0 to H-1
        For k = 0 to kₕ-1
                cₖ^{(h)} = c_{R}_{ₖ}^{(h)};
        End for
End for
```

In a first specific example with K=6, an input bit sequence c=[c₀, c₁, c₂, c₃, c₄, c₅], H=2 component repetition index sets R⁽⁰⁾={0, 1, 2, 3, 4, 5} with K₀=6 and R⁽¹⁾={0, 1, 2} with K₁=3, the 0th component repetition output bit sequence c⁽⁰⁾=[c₀⁽⁰⁾, c₁⁽⁰⁾, c₂⁽⁰⁾, c₃⁽⁰⁾, c₄⁽⁰⁾, c₅⁽⁰⁾]=[c_{R}_{₀}_{⁽⁰⁾}, c_{R}_{₁}_{⁽⁰⁾}, c_{R}_{₂}_{⁽⁰⁾}, c_{R}_{₃}_{⁽⁰⁾}, c_{R}_{₄}_{⁽⁰⁾}, c_{R}_{₅}_{⁽⁰⁾}]=[c₀, c₁, c₂, c₃, c₄, c₅] and the 1^{st} component repetition output bit sequence c⁽¹⁾=[c₀⁽¹⁾, c₁⁽¹⁾, c₂⁽¹⁾]=[c_{R}_{₀}_{⁽¹⁾}, c_{R}_{₁}_{⁽¹⁾}, c_{R}_{₂}_{⁽¹⁾}]=[c₀, c₁, c₂].

In a second specific example with K=6, an input bit sequence c=[c₀, c₁, c₂, c₃, c₄, c₅], H=3 component repetition index sets R⁽⁰⁾={0, 1, 2, 3, 4, 5} with K₀=6, R⁽¹⁾={0, 1, 2} with K₁=3 and R⁽²⁾={4} with K₂=1, the 0th component repetition output bit sequence c⁽⁰⁾=[c₀⁽⁰⁾, c₁⁽⁰⁾, c₂⁽⁰⁾, c₃⁽⁰⁾, c₄⁽⁰⁾, c₅⁽⁰⁾]=[c_{R}_{₀}_{⁽⁰⁾}, c_{R}_{₁}_{⁽⁰⁾}, c_{R}_{₂}_{⁽⁰⁾}, c_{R}_{₃}_{⁽⁰⁾}, c_{R}_{₄}_{⁽⁰⁾}, c_{R}_{₅}_{⁽⁰⁾}]32 [c₀, c₁, c₂, c₃, c₄, c₅], the 1^{st} component repetition output bit sequence c⁽¹⁾=[c₀⁽¹⁾, c₁⁽¹⁾, c₂⁽¹⁾]=[c_{R}_{₀}_{⁽¹⁾}, c_{R}_{₁}_{⁽¹⁾}, c_{R}_{₂}_{⁽¹⁾}]=[c₀, c₁, c₂] and the 2^{nd} component repetition output bit sequence c⁽²⁾=[c₀⁽²⁾]=[c_{R}_{₀}_{⁽²⁾}]=[c₄]. In a third specific example with K=6, an input bit sequence c=[c₀, c₁, c₂, c₃, c₄, c₅], H=3 component repetition index sets R⁽⁰⁾={0, 1, 2, 3, 4} with K₀=5, R⁽¹⁾={5, 0} with K₁=2, and R⁽²⁾={4} with K₂=1, the 0th component repetition output bit sequence c=[c₀, c₁, c₂, c₃, c₄, c₅], H=3 component repetition index sets R⁽⁰⁾={0, 1, 2, 3, 4} with K₀5, R⁽¹⁾={5, 0} with K₁=1, and R⁽²⁾={4} with K₂=1, the 0th component repetition output bit sequence c⁽⁰⁾=[c₀⁽⁰⁾, c₁⁽⁰⁾, c₂⁽⁰⁾, c₃⁽⁰⁾, c₄⁽⁰⁾]=[c_{R}_{₀}_{⁽⁰⁾}, c_{R}_{₁}_{⁽⁰⁾}, c_{R}_{₂}_{⁽⁰⁾}, c_{R}_{₃}_{⁽⁰⁾}, c_{R}_{₄}_{⁽⁰⁾}]=[c₀, c₁, c₂, c₃, c₄], the 1^{st} component repetition output bit sequence c⁽¹⁾=[c₀⁽¹⁾, c₁⁽¹⁾]=[c_{R}_{₀}_{⁽¹⁾}, c_{R}_{₁}_{⁽¹⁾}]=[c₅, c₀] and the 2^{nd} component repetition output bit sequence c⁽²⁾=[c₀⁽²⁾]=[c_{R}_{₀}_{⁽²⁾}]=[c₄]

In some embodiment, the repetition comprises obtaining, by the first node, the input bit sequence c=[c₀, c₁, . . . , c_{K-1}] of length K; and performing, by the first node, an rate profiling on the input bit sequence c=[c₀, c₁, . . . , c_{K-1}] using the first data bit index set Q={Q₀, Q₁, . . . , Q_{K-1}} to obtain a repetition rate profile output bit sequence v′=[v′₀, v′₁, . . . , v′_{N-1}] of length N as

```
k = 0;
For i = 0 to N-1
      If i ϵ Q
          v′ᵢ = cₖ;
          k = k + 1;
      Else
          v′ᵢ = 0;
      End if
End for
```

determining, by the first node, the H component repetition output bit sequences c⁽⁰⁾, c⁽¹⁾, . . . , c^{(H-1)} by at least one of the following:
the first data bit index set Q={Q₀, Q₁, . . . , Q_{K-1}},
the H component repetition lengths K₀, K₁, . . . , K_{H-1},
wherein, for h=0, 1, . . . , H−1, the h-th component repetition output bit sequence c^{(h})=[c₀^{(h)}, c₁^{(h)}, . . . , c_{K}_{ₕ}₋₁^{(h)}] is of length Kₕ.

In some embodiments, for h=0, 1, . . . , H−1, the repetition determines the h-th component repetition output bit sequence c^{(h)} by setting the k-th bit cₖ^{(h)} in the h-th component repetition output bit sequence c^{(h)} to the bit with an index Qₖ in the repetition rate profile output bit sequence v′=[v′₀, v′₁, . . . , v′_{N-1}], i.e., cₖ^{(h)}=v′_{Q}_{ₖ}, wherein Qₖ is the k-th element in the first data bit index set Q and a pseudo-code is as follows.

```
For h = 0 to H−1
  For k = 0 to Kₕ−1
    cₖ^{(h)} = v′_{Qk};
  End for
End for
```

In a first specific example with K=6, an input bit sequence c=[c₀, c₁, c₂, c₃, c₄, c₅], H=2 polar matrix sizes N₀=16 and N₁=8, a first data bit index set Q={12, 7, 11, 13, 14, 15}, K₀=6, K₁=3, we obtain a repetition rate profile output bit sequence v′=[v′₀, v′₁, . . . , v′_{N-1}]=[v′₀, v′₁, v′₂, v′₃, v′₄, v′₅, v′₆, v′₇, v′₈, v′₉, v′₁₀, v′₁₁, v′₁₂, v′₁₃, v′₁₄, v′₁₅ ] of length Nₘ=max(N₀, N₁)=16, then we obtain the 0th component repetition output bit sequence c⁽⁰⁾=[c₀⁽⁰⁾, c₁⁽⁰⁾, c₂⁽⁰⁾, c₃⁽⁰⁾, c₄⁽⁰⁾, c₅⁽⁰⁾]=[v′_{Q}_{₀}, v′_{Q}_{₁}, v′_{Q}_{₂}, v′_{Q}_{₃}, v′_{Q}_{₄}, v′_{Q}_{₅}]=[v′₁₂, v′₇, v′₁₁, v′₁₃, v′₁₄, v′₁₅] and the 1^{st} component repetition output bit sequence c⁽¹⁾=[c₀⁽¹⁾, c₁⁽¹⁾, c₂⁽¹⁾]=[v′_{Q}_{₀}, v′_{Q}_{₁}, v′_{Q}_{₂}]=[v′₁₂, v′₇, v′₁₁].

In some embodiments, at least two of H repetition output bit sequences c⁽⁰⁾, c⁽¹⁾, c⁽²⁾, . . . , c^{(H-1)} comprises the Qₖ-th bit v′_{Q}_{ₖ} in the repetition rate profile output bit sequence v′=[v′₀, v′₁, . . . , v′_{N-1}] of length N, wherein k is non-negative integer smaller than the size of the first data bit index set Q; Qₖ is the k-th element in the first data bit index set Q. A specific example is all repetition output bit sequences c⁽⁰⁾, c⁽¹⁾, c⁽²⁾, . . . , c^{(H-1)} comprises the Q₀-th bit v′_{Q}_{₀} in the repetition rate profile output bit sequence v′=[v′₀, v′₁, . . . , v′_{N-1}] of length N, wherein a specific example is c₀⁽⁰⁾=c₀⁽¹⁾= . . . =c₀^{(H-2)}=c₀^{(H-1)}=v′_{Q}_{₀}.

In some embodiments, at least two of H repetition output bit sequences c⁽⁰⁾, c⁽¹⁾, c⁽²⁾, . . . , c^{(H-1)} comprises the k-th bit cₖ in the input bit sequence c=[c₀, c₁, . . . , c_{K-1}] of length K. A specific example is all repetition output bit sequences c⁽⁰⁾, c⁽¹⁾, c^{(H-1)} comprises the 0-th bit c₀ in the input bit sequence c=[c₀, c₁, . . . , c_{K-1}] of length K, wherein a specific example is c₀⁽⁰⁾=c₀⁽¹⁾= . . . =c₀^{(H-2)}=c₀^{(H-1)}==c₀.

In some embodiments, at least two of H repetition output bit sequences c⁽⁰⁾, c⁽¹⁾, c⁽²⁾, . . . , c^{(H-1)} are of the same length, i.e., there exists h≠k such that Kₕ=Kₖ, wherein for h=0, 1, . . . , H−1, Kₕ is the length of the h-th repetition output bit sequences c^{(h)}. A specific example with H=3, all repetition output bit sequences c⁽⁰⁾, c⁽¹⁾, c⁽²⁾ are of length K₀=K₁=K₂=2.

In some embodiments, not all repetition output bit sequences c⁽⁰⁾, c⁽¹⁾, c⁽²⁾, . . . , c^{(H-1)} are of the same length, i.e., there exists h≠k such that Kₕ≠Kₖ, wherein Kₕ is the length of the h-th repetition output bit sequence c^{(h)} and Kₖ is the length of the k-th repetition output bit sequence c^{(k)}. A specific example with H=3, the 0-th repetition output bit sequence c⁽⁰⁾ is of length K₀=6 and the 1^{st} repetition output bit sequence c⁽¹⁾ is of length K₁=3, wherein K₀≠K₁.

In some embodiments, all repetition output bit sequences c⁽⁰⁾, c⁽¹⁾, c⁽²⁾, . . . , c^{(H-1)} are of different lengths, i.e., if h≠k, Kₕ≠Kₖ, wherein Kₕ is the length of the h-th repetition output bit sequence c^{(h)} and Kₖ is the length of the k-th repetition output bit sequence c^{(k)}. A specific example with H=3, the 0-th repetition output bit sequence c⁽⁰⁾ is of length K₀=6, the 1^{st} repetition output bit sequence c⁽¹⁾ is of length K₁=3, and the 2^{nd} repetition output bit sequence c⁽²⁾ is of length K₂=1, wherein K₀≠K₁, K₀≠K₂, and K₁≠K₂.

### Embodiment 5

This section discloses examples involving a component rate profiling.

Embodiment 5 is based on the above embodiments.

In some embodiments, for h=0, 1, . . . , H−1, the h-th component repetition output bit sequence c^{(h)}=[c₀^{(h)}, c₁^{(h)}, . . . , c_{K}_{ₕ}₋₁^{(h)}] of length Kₕ is input to a component rate profiling to determine an h-th component rate profiling output bit sequence v^{(h)}=[v₀^{(h)}, v₁^{(h)}, . . . , v_{N}_{ₕ}₋₁^{(h)}] of length Nₕ using the h-th component data bit index set Q^{(h)}={Q₀^{(h)}, Q₁^{(h)}, . . . , Q_{K}_{ₕ}₋₁^{(h)}}, wherein, Nₕ is the polar matrix size of the h-th component polar matrix G^{(N}^{ₕ}⁾, specific examples are given in FIGS. 4A to 4C.

The component rate profiling determining an component rate profiling output bit sequence v=[u₀, v₁, . . . , v_{N-1}] comprises obtaining, by the first node, a component rate profiling input bit sequence c′=[c′₀, c′₁, . . . , c′_{K-1}]; and determining, by the first node, a component rate profiling output bit sequence v=[v₀, v₁, . . . , v_{N-1}] by a component rate profiling using a component data bit index set Q′={Q′₀, Q′₁, . . . , Q′_{K′-1}} of size K′; wherein, K′ is a component repetition length; N is the polar matrix size of a component polar matrix G^{(N)}.

### Component Data Bit Index Set Q′

In some embodiments, the component data bit index set Q′ is a subset of a fourth-type integer set Z_{N}={0, 1, 2, . . . , N−2, N−1}, wherein, the fourth-type integer set Z_{N}={0, 1, 2, . . . , N−2, N−1} comprises and only comprises all non-negative integers smaller than N. The component data bit index set Q′={Q′₀, Q′₁, . . . , Q′_{K′-1}} has K′ non-negative elements Q′₀, Q′₁, . . . , Q′_{K-2}, Q′_{K-1}, i.e., the component data bit index set Q′is of size K′. In some embodiments, for k=0, 1, . . . , K′−2, the element Q′ₖ in the component data bit index set Q′is smaller than Q′ₖ₊₁, i.e., the component data bit index set Q′ is sorted in ascending order according to index values with Q′₀<Q′₁< . . . <Q′_{K′-2}<Q′_{K′-1}. In some embodiments, for k=0, 1, . . . , K′−2, the reliability of the Q′ₖ-th polarized sub-channel (denoted as W(Q′ₖ)) is smaller than the reliability of the Q′ₖ₊₁-th polarized sub-channel (denoted as W(Q′ₖ₊₁)), i.e., the component data bit index set Q′ is sorted in ascending order according to the polarized sub-channel reliability with W(Q′₀)<W(Q′₁)< . . . <W(Q′_{K′-2})<W(Q′_{K′-1}). In some embodiments, for k=0, 1, . . . , K′−2, the element Q′ₖ in the component data bit index set Q′ is greater than Q′ₖ₊₁, i.e., the component data bit index set Q′ is sorted in descending order according to index values with Q′₀>Q′₁> . . . >Q′_{K′-2}>Q′_{K-1}. In some embodiments, for k=0, 1, . . . , K′−2, the reliability of the Q′ₖ-th polarized sub-channel (denoted as W(Q′ₖ)) is greater than the reliability of the Q′ₖ₊₁-th polarized sub-channel (denoted as W(Q′ₖ₊₁)), i.e., the component data bit index set Q′ is sorted in descending order according to the polarized sub-channel reliability with W(Q′₀)>W(Q′₁)> . . . >W(Q′_{K′-2})>W(Q′_{K′-1}).

In a first specific example with N=8 and K′=4, a component data bit index set is Q′={Q′₀, Q′₁, Q′₂, Q′₃}={3, 5, 6, 7}. In a second specific example with N=32 and K′=25, a component data bit index set is Q′={Q′₀, Q′₁, Q′₂, Q′₃, Q′₄, Q′₅, Q′₆, Q′₇, Q′₈, Q′₉, Q′₁₀, Q′₁₁, Q′₁₂, Q′₁₃, Q′₁₄, Q′₁₅, Q′₁₆, Q′₁₇, Q′₁₈, Q′₁₉, Q′₂₀, Q′₂₁, Q′₂₂, Q′₂₃, Q′₂₄}={5, 9, 6, 17, 10, 18, 12, 20, 24, 7, 11, 19, 13, 14, 21, 26, 25, 22, 28, 15, 23, 31, 27, 29, 30} with polarized sub-channel reliability with W(Q′₀)<W(Q′₁)<W(Q′₂)<W(Q′₃)<W(Q′₄)<W(Q′₅)<W(Q′₆)<W(Q′₇)<W(Q′₈)<W(Q′₉) <W(Q′₁₀)<W(Q′₁₁)<W(Q′₁₂)<W(Q′₁₃)<W(Q′₁₄)<W(Q′₁₅)<W(Q′₁₆)<W(Q′₁₇)<W(Q′₁₈)<W(Q′₁₉)<W(Q′₂₀)<W(Q′₂₁)<W(Q′₂₂)<W(Q′₂₃)<W(Q′₂₄). In a third specific example with N=8 and K′=4, a component data bit index set is Q′={Q′₀, Q′₁, Q′₂, Q′₃}={7, 6, 5, 3}.

In some embodiments, the component rate profiling determines the component rate profiling output bit sequence v=[v₀, v₁, . . . , v_{N-1}] corresponding to the component rate profiling input bit sequence c′=[c′₀, c′₁, . . . , c′_{K′-1}] according to the component data bit index set Q′ is as follows.

```
For each index i = 0, 1, ..., N−1,
    if the index i belongs to the component data
    bit index set Q′, the i-th bit vᵢ
  in the component rate profiling output bit sequence
  v is set to a bit in the component rate profiling input bit sequence c′;
    if the index i does not belongs to the data
    bit index set Q′, the i-th bit vᵢ in
  the component rate profiling output
  bit sequence v is set to a bit zero (“0”);
End for
```

wherein, a specific example pseudo-code for the rate profiling is as follows.

```
k = 0;
For i = 0 to N − 1
  If i ∈ Q′
    vᵢ = c′ₖ;
    k = k + 1;
  Else
    vᵢ = 0;
  End if
End for
```

In some embodiments, for an index i belonging to the component data bit index set Q′, the bit vᵢ in the component rate profiling output bit sequence v is set to a bit in the component rate profiling input bit sequence c′.

A first specific example with N=8, K′=3 and a component data bit index set Q′={5, 6, 7}, a component rate profiling input bit sequence c′=[c′₀, c′₁, c′₂], the bits v₅, v₆, v₇ with indices belonging to the component data bit index set Q′={5, 6, 7} in a component rate profiling output bit sequence v=[v₀, v₁, v₂, v₃, v₄, v₅, v₆, v₇] is set as v₅=c′₀, v₆=c′₁, and v₇=c′₂.

A second specific example with N=16, K′=6 and a component data bit index set Q′={12, 7, 11, 13, 14, 15}, a component rate profiling input bit sequence c′=[c′₀, c′₁, c′₂, c′₃, c′₄, c′₅], the bits v₁₂, v₇, v₁₁, v₁₃, v₁₄, v₁₅ with indices belonging to the data bit index set Q′={12, 7, 11, 13, 14, 15} in a component rate profiling output bit sequence v=[v₀, v₁, v₂, v₃, v₄, v₅, v₆, v₇, v₈, v₉, v₁₀, v₁₁, v₁₂, v₁₃, v₁₄, v₁₅] is set as v₁₂=c′₀, v₇=c′₁, v₁₁=c′₂, v₁₃=c′₃, v₁₄=c′₄, and v₁₅=c′₅.

A third specific example is given as

```
k = 0;
For i = 0 to N−1
  If i ∈ Q′
    vᵢ = c′ₖ;
    k = k + 1;
  Else
    vᵢ = 0;
  End if
End for
```

In some embodiments, for a index i not belonging to the component data bit index set Q′, the bit vᵢ in the component rate profiling output bit sequence v is equal to 0.

A first specific example with N=8, K′=3 and Q′={5, 6, 7}, the bits v₀, v₁, v₂, v₃, v₄ with indices not belonging to the component data bit index set Q′={5, 6, 7} in a component rate profiling output bit sequence v=[v₀, v₁, v₂, v₃, v₄, v₅, v₆, v₇] is set as v₀=0, v₁=0, v₂=0, v₃=0, and v₄=0.

A second specific example with N=16, K′=6 and Q′={7, 11, 12, 13, 14, 15}, the bits v₀, v₁, v₂, v₃, v₄, v₅, v₆, v₈, v₉, v₁₀ with indices not belonging to the component data bit index set Q′={7, 11, 12, 13, 14, 15} in a component rate profiling output bit sequence v=[v₀, v₁, v₂, v₃, v₄, v₅, v₆, v₇, v₈, v₉, v₁₀, v₁₁, v₁₂, v₁₃, v₁₄, v₁₅] is set as v₀=0, v₁=0, v₂=0, v₃=0, v₄=0, v₅=0, v₆=0, v₈=0, v₉=0, and v₁₀=0.

A third specific example is given as

```
k = 0;
For i = 0 to N−1
  If i ∈ Q′
    vᵢ = c′ₖ;
    k = k + 1;
  Else
    vᵢ = 0;
  End if
End for
```

In some embodiments, the component rate profiling output bit sequence v is the multiplexing of the component rate profiling input bit sequence c′ and an all-zero sequence of length N−K′, wherein N is the polar matrix size and K′ is the component rate profiling input bit sequence length.

A first specific example with N=8 and K′=3 is a component rate profiling input bit sequence c′=[c′₀, c′₁, c′₂] and an all-zero sequence of length N−K′=8−3=5, then a component rate profiling output bit sequence v=[v₀, v₁, v₂, v₃, v₄, v₅, v₆, v₇]=[0, 0, 0, 0, 0, c₀, c₁, c₂].

A second specific example with N=16, K′=6, a component rate profiling input bit sequence c′=[c′₀, c′₁, c′₂, c′₃, c′₄, c′₅] and an all-zero sequence of length N−K′=16−4=12, then a component rate profiling output bit sequence v=[v₀, v₁, v₂, v₃, v₄, v₅, v₆, v₇, v₈, v₉, v₁₀, v₁₁, v₁₂, v₁₃, v₁₄, v₁₅]=[0, 0, 0, 0, 0, 0, 0, 0, 0, 0, c₀, 0, c₁, c₂, c₃] is determined.

### Embodiment 6

This section discloses examples involving a first concatenation.

Embodiment 6 is based on the above embodiments. The input of a concatenation operation can be based on the input sequence c.

In some examples, the concatenation block can be connected with one or more component rate profile block.

In some embodiments, the H component rate profiling output bit sequences v⁽⁰⁾, v⁽¹⁾, . . . , v^{(H-1)} are input to a first concatenation to determine a concatenation output bit sequence y=[y₀, y₁, y₂, . . . , y_{E-1}] of length E, wherein, for h=0, 1, . . . , H−1, Nₕ is the length of the h-th component rate profiling output bit sequence v^{(h)}=[v₀^{(h)}, v₁^{(h)}, . . . , v_{N}_{ₕ}₋₁^{(h)}]; E=N₀+N₁+ . . . +N_{H-1} is the length of the output bit sequence e=[e₀, e₁, e₂, . . . , e_{E-1}], wherein, Nₕ is also the polar matrix size of the h-th component polar matrix G^{(N}^{ₕ}⁾;

Examples of systems involving a first concatenation block are given in FIGS. 4A to 4C.

In some embodiments, the first concatenation comprises obtaining, by the first node, H component concatenation input bit sequences v⁽⁰⁾, v⁽¹⁾, . . . , v^{(H-1)}; and determining, by the first node, a concatenation output bit sequence y=[y₀, y₁, y₂, . . . , y_{E-1}] as y=[v⁽⁰⁾, v⁽¹⁾, . . . , v^{(H-1)}]=[v₀⁽⁰⁾, v₁⁽⁰⁾, . . . , v_{N}_{₀}₋₁⁽⁰⁾, v₀⁽¹⁾,v₁⁽¹⁾, . . . , v_{N}_{₁}₋₁⁽¹⁾, . . . , v₀^{(H-1)}, v₁^{(H-1)}, . . . , v_{N}_{_{H−1}}₋₁^{(H-1)}].

Here, E is the length of the output bit sequence e=[e₀, e₁, e₂, . . . , e_{E-1}]; for h=0, 1, . . . , H−1, the h-th component concatenation input bit sequence v^{(h)}=[v₀^{(h)}, v₁^{(h)}, . . . , v_{N}_{ₕ}₋₁^{(h)}] is of length Nₕᵢ; wherein, Nₕ is the h-th component polar matrix size; The output length is equal to the summation of the length of H component concatenation input bit sequences v⁽⁰⁾, v⁽¹⁾, . . . , v^{(H-1)}, i.e., E=N₀+N₁+ . . . +N_{H-1}. In some embodiments, for h=0, 1, . . . , H−1, the h-th component concatenation input bit sequence is the h-th component rate profiling output bit sequence.

The purpose of the concatenation block is to combine the multiple input sequences to generate an output sequence, which can be used as input for other blocks within a system.

In some example, the first concatenation may comprise obtaining, by the first node, H component concatenation input bit sequences v⁽⁰⁾, v⁽¹⁾, . . . , v^{(H-1)}; and determining, by the first node, a concatenation output bit sequence y=[y₀, y₁, y₂, . . . , y_{E-1}] as

```
i = 0;
For h = 0 to H−1
  For k = 0 to Nₕ−1
    yᵢ = vₖ^{(h)};
    i = i + 1;
  End for
End for
```

Here, E is the length of the output bit sequence e=[e₀, e₁, e₂, . . . , e_{E-1}]; for h=0, 1, . . . , H−1, the h-th component concatenation input bit sequence v^{(h)}=[v₀^{(h)}, v₁^{(h)}, . . . , v_{N}_{ₕ}₋₁^{(h)}] is of length Nₕ; wherein, Nₕ is the h-th component polar matrix size; The output length is equal to the summation of the length of H concatenation input bit sequences v⁽⁰⁾, v⁽¹⁾, . . . , v^{(H-1)}, i.e., E=N₀+N₁+ . . . +N_{H-1}. In some embodiments, for h=0, 1, . . . , H−1, the h-th component concatenation input bit sequence is the h-th component rate profiling output bit sequence.

### Embodiment 7

This section discloses examples related to pre-transform.

Embodiment 7 is based on the above embodiments.

The input of a pre-transform can be based on the input sequence.

In some examples, a pre-transform block is connected with a concatenation block.

In some embodiments, the concatenation output bit sequence y=[y₀, y₁, y₂, . . . , Y_{E-1}] of length E is input to a pre-transform to determine a pre-transform output bit sequence u=[u₀, u₁, u₂, . . . , u_{E-1}] of length E by at least one of the following: the generator polynomial g(D)=g₀+g₁·D+g₂·D²+ . . . +gₘ·D^{m} over GF(2), the recursive feedback polynomial q(D)=q₀+q₁·D+q₂·D²+ . . . +qₘ·D^{m} over GF(2).

A pre-transform operation can be conducted based on either a generator polynomial or a recursive feedback polynomial.

In some embodiments, the pre-transform comprises obtaining, by the first node, a pre-transform input bit sequence of length N, and determining, by the first node, a pre-transform output bit sequence u=[u₀, u₁, . . . , u_{N-1}] by using at least one of the following: the generator polynomial g(D)=g₀+g₁·D+ . . . +gₘ·D^{m} over GF(2), the recursive feedback polynomial q(D)=q₀+q₁·D+ . . . +qₘ·D^{m} .

In the above example, N can be any positive integer; m is a memory length; specific examples are given in FIGS. 4A to 4C. In some embodiments, the pre-transform input bit sequence of length N is the concatenation output bit sequence y=[y₀, y₁, y₂, . . . , y_{E-1}] of length E, wherein N =E, the concatenation output bit sequence y=[y₀, y₁, y₂, . . . , y_{E-1}] of length E comprises more than one component rate profiling output bit sequence. In some embodiments, the pre-transform input bit sequence of length N comprises more than one component rate profiling output bit sequence.

(Pre-Transform Using a Generator Polynomial g(D)

In some embodiments, the pre-transform determines the pre-transform output bit sequence u corresponding to the pre-transform input bit sequence y=[y₀, y₁, y₂, . . . , y_{E-1}] of length E according to a generator polynomial g(D)=g₀+g₁·D+g₂·D+ . . . +gₘ₋₁·D+gₘ·D, wherein m is called a memory length of the generator polynomial g(D). The generator polynomial g(D)=g₀+g₁·D+ . . . +gₘ₋₁·D^{m-1}+g^{m}·D^{m} can be any binary polynomial over GF(2), wherein m is the polynomial degree or the memory length. In a specific example with a memory length m=6, a generator polynomial is g(D)=g₀+g₁·D+g₂·D²+g₃·D³+g₄·⁴D+g₅·D⁵+g₆·D⁶=1+0·D+1·D²+1·D³⁺⁰·D⁴+1·D⁵+1·D⁶=1+D²+D³+D⁵+D⁶. In another specific example with a memory length m=3, a generator polynomial is g(D)=g₀+g₁·D+g₂·D²+g₃·D³=1+1·D+0·D²+1·D³=1+D+D³.

FIG. 3 shows an example diagram of a pre-transform using a generator polynomial g(D)=g₀+g₁·D+ . . . +gₘ₋₁·D^{m-1}+gₘ·D^{m} of a memory length m, wherein a bit uᵢ with an index i in a pre-transform output bit sequence u is determined by m+1 bit yᵢ, yᵢ₋₁, yᵢ₋₂, . . . , yᵢ₋ₘ with consecutive indices i, i−1, i−2, . . . , i−m in a pre-transform input bit sequence y and the generator polynomial g(D)=g₀+g₁·D+ . . . +gₘ₋₁·D^{m--1}+gₘ·D^{m} as

$${u}_{i} = {\sum }_{k = 0}^{m} {g}_{k} \cdot {y}_{i - k} ,$$

wherein the summation and the multiplication is over GF(2); the bit yᵢ₋ₖ=0 for i<k; gₖ is a coefficient of the term with degree K in the generator polynomial g(D)=g₀+g₁·D+ . . . +gₘ₋₁·D^{m-1}+gₘ·D^{m} over GF(2); a specific pseudo code is as follows.

```
For i = 0 to N−1
  k = 0;
  uᵢ = 0;
  While k ≤ m && k ≤ i
    uᵢ = mod(uᵢ + gₖ·yᵢ₋ₖ, 2);
    k = k + 1;
  End while
End for
```

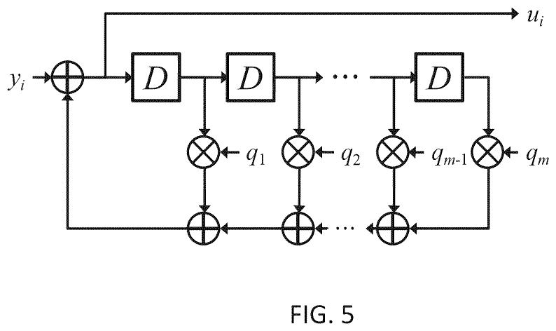

FIG. 5 shows an specific example of a pre-transform defined by a recursive feedback polynomial q(D)=q₀+q₁·D+ . . . +qₘ₋₁·D^{m-1}+qₘ·D^{m} over GF(2) with q₀=1.

(Pre-Transform Using a Recursive Feedback Polynomial q(D))

In some embodiments, the pre-transform determines the pre-transform output bit sequence u corresponding to the pre-transform input bit sequence y according to a recursive feedback polynomial q(D)=q₀+q₁·D+q₂·D+ . . . +qₘ₋₁·D+qₘ·D, wherein m is called a memory length of the recursive feedback polynomial q(D).

The feedback polynomial q(D)=q₀+q₁·D+ . . . +qₘ₋₁·D^{m-1}+qₘ·D^{m} is a binary polynomial with the zero-degree coefficient q₀ being 1 and other coefficients q₁, . . . , qₘ being any binary values over GF(2), wherein m is a memory length. In a specific example with a memory length m=6, a feedback polynomial is q(D)=q₀+q₁·D+q₂·D²+q₃·D₃+q₄·D₄+q₅·D₅+q₆·D₆=1+0·D+1·D² +0·D3+1·D⁴+1·D⁵+1·D⁶=1+D²+D⁴+D⁵+D⁶. In another specific example with a memory length m=3, a feedback polynomial is q(D)=q₀+q₁·D+q₂·D²+q₃·D₃=1+0·D+1·D²+1·D³=1+D²+D³.

FIG. 5 shows an example diagram of a pre-transform using a recursive feedback polynomial q(D)=q₀+q₁·D+ . . . +qₘ₋₁·D^{m-1}+qₘ·D^{m} with q₀=1 and a memory length m, wherein a bit uᵢ with an index i in a pre-transform output bit sequence u is determined by the following:
a bit vᵢ with an index i in a pre-transform input bit sequence y=[y₀, y₁, . . . , y_{E-1}],
m previous bits uᵢ₋₁, uᵢ₋₂, . . . , uᵢ₋ₘ with consecutive indices i−1, i−2, . . . , i−m in a pre-transform output bit sequence u,
a recursive feedback polynomial q(D)=q₀+q₁·D+ . . . +qₘ₋₁·D^{m-1}+qₘ·D^{m} with q₀=1,
wherein a specific example

$${u}_{i} = {y}_{i} + {\sum }_{k = 1}^{m} {q}_{k} \cdot {u}_{i - k}$$

is with the summation and the multiplication is over GF(2); the bit uᵢ₋ₖ=0 for i<k; qₖ is a coefficient of the term with degree k in the recursive feedback polynomial q(D)=q₀+q₁·D+ . . . +qₘ₋₁·D^{m-1}+qₘ·D^{m} over GF(2); a specific pseudo code is as follows.

```
For i = 0 to N−1
  k = 1;
  uᵢ = yᵢ,
  While k ≤ m && k ≤ i
    uᵢ = mod(uᵢ + qₖ·uᵢ₋ₖ, 2);
    k = k + 1;
  End while
End for
```

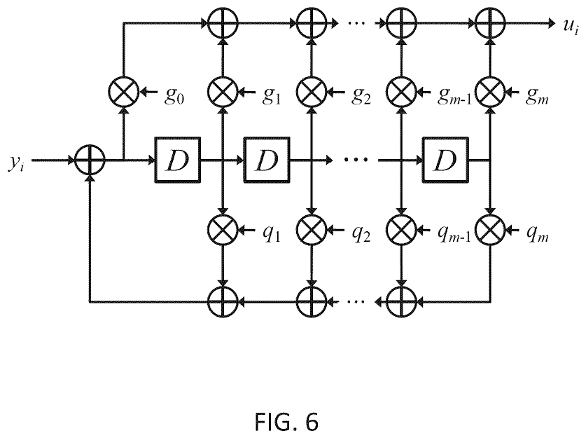

FIG. 6 shows another specific example of a pre-transform defined by both a generator polynomial g(D)=g₀+g₁·D+ . . . +gₘ₋₁·D^{m-1}+gₘ·D^{m} and a recursive feedback polynomial q(D) =q₀+q₁·D+ . . . +qₘ₋₁·D^{m-1}+qₘ·D^{m} over GF(2) with q₀=1.

(Pre-Transform Using Both a Generator Polynomial g(D) and a Recursive Feedback Polynomial q(D)

In some embodiments, the pre-transform determines the pre-transform output bit sequence u corresponding to the pre-transform input bit sequence y according to both a generator polynomial g(D)=g₀+g₁·D+ . . . +gₘ₋₁·D^{m-1}+gₘ·D and a recursive feedback polynomial q(D)=q₀+q₁·D+ . . . +qₘ₋₁·D^{m-1}+qₘ·D^{m}, wherein m is called a memory length for both the generator polynomial g(D) and the recursive feedback polynomial q(D).

The generator polynomial g(D)=g₀+g₁·D+ . . . +gₘ₋₁·D^{m-1}+gₘ·D^{m} can be any binary polynomial over GF(2), wherein m is the polynomial degree or the memory length. In a specific example with a memory length m=6, a generator polynomial is g(D)=g₀+g₁·D+g₂·D²+g₃·D³+g₄·D⁴+g₅·D⁵+g₆·D⁶=1+0·D+1·D²+1·D³+0·D⁴+1·D⁵+1·D⁶=1+D²+D³+D⁵+D⁶. In another specific example with a memory length m=3, a generator polynomial is g(D)=g₀+g₁·D+g₂·D²+g₃·D³=1+1·D+0·D²+1·D³=1+D+D³. The recursive feedback polynomial q(D)=q₀+q₁·D+ . . . +qₘ₋₁·D^{m-1}+qₘ·D^{m} is a binary polynomial with the zero-degree coefficient q₀ being 1 and other coefficients q₁, . . . , qₘ being any binary values over GF(2), wherein m is the memory length. In a specific example with a memory length m=6, a recursive feedback polynomial is q(D)=q₀+q₁·D+q₂·D²+q₃·D³+q₄·D⁴+q₅·D⁵+q₆·D⁶=1+0·D+1·D²+0·D³+1·D⁴+1·D⁵+1·D⁶=1+D²+D⁴+D⁵+D⁶. In another specific example with a memory length m=3, a recursive feedback polynomial is q(D)=q₀+q₁·D+q₂·D²+q₃·D³=1+0·D+1·D²+1·D³=1+D²+D³.

FIG. 6 shows a diagram of a pre-transform using both a generator polynomial and a recursive feedback polynomial.

As shown in FIG. 6, a generator polynomial g(D)=g₀+g₁·D+ . . . +gₘ₋₁·D^{m-1}+gₘ·D^{m} and a recursive feedback polynomial q(D), wherein the pre-transform determines a bit uᵢ with an index i in a pre-transform output bit sequence u comprising:
setting, by the first node, a bit t₀ with an index 0 in a state bit sequence t=[t₀, t₁, t₂, . . . , tₘ] to be a bit yᵢ with an index i of a pre-transform input bit sequence y=[y₀, y₁, y₂, . . . , y_{E-1}], i.e., t₀=yᵢ; and
determining, by the first node, a summation bit s by the recursive feedback polynomial q(D) =q₀+q₁·D+ . . . +qₘ·D^{m} over GF(2) and the updated state bit sequence t=[t₀, t₁, t₂ . . . , tₘ₋₁, tₘ] as s=mod(Σⱼ₌₀^{m}qⱼ·tⱼ, 2), and
setting, by the first node, a bit t₀ with an index 0 in the state bit sequence t=[t₀, t₁, t₂ . . . , tₘ₋₁, tₘ] to the summation bit s, i.e., t₀=s, and
determining, by the first node, a bit uᵢ with an index i of a pre-transform output bit sequence u=[u₀, u₁, u₂, . . . , u_{N-1}] by a generator polynomial g(D)=g₀+g₁·D+ . . . +gₘ·D^{m} (or equivalently a generator bit sequence g=[g₀, g₁, . . . , gₘ]) over GF(2) and the updated state bit sequence t=[t₀, t₁, . . . , tₘ₋₁, tₘ] as uᵢ=mod(Σⱼ₌₀^{m}gⱼ·tⱼ, 2).
performing, by the first node, a right shift on the state bit sequence t=[t₀, t₁, . . . , tₘ₋₁, tₘ] with a bit t₀ with index 0 in the state bit sequence t=[t₀, t₁, . . . , tₘ₋₁, tₘ] is set to 0 as follows:

For j = m to 1
tⱼ = tⱼ₋₁;
End for
t₀ = 0;

A specific pseudo code for the above steps is as follows.

```
For j = 0 to m
  tⱼ = 0;
End for
k = 0;
For i = 0 to N−1
  s = 0;
  t₀ = yᵢ;
  For j = 0 to m
    s = mod(s + qⱼ·tⱼ, 2);
  End for
  t₀ = S;
  uᵢ = 0;
  For j = 0 to m
    uᵢ = mod(uᵢ + gⱼ·tⱼ, 2);
  End for
  For j = m to 1
    tⱼ = tⱼ₋₁;
  End for
End for
```

### Embodiment 8

This section discloses examples related to segmentation.

Embodiment 8 is based on all of the above embodiments.

In some examples, the input of a segmentation block is based on the input sequence c.

In some examples, a segmentation block can relate to a pre-transform block.

In some embodiments, the pre-transform output bit sequence u=[u₀, u₁, u₂, . . . , u_{E-1}] of length E is input to a segmentation to determine H segmentation output bit sequences u₍₀₎, u₍₁₎, . . . u_{(H-1)} by H component polar matrix sizes N₀, N₁, . . . , N_{H-1}, wherein, H is the number of component polar matrices; for h=0, 1, . . . , H−1, the h-th segmentation output bit sequence u^{(h)} is of length Nₕ, wherein Nₕ is the h-th component polar matrix size and E is the length of the pre-transform output bit sequence u and E=N₀+N₁+ . . . +N_{H-1}.

In some examples, the segmentation operation comprises obtaining, by the first node, a segmentation input bit sequence of length E; and determining, by the first node, H segmentation output bit sequences u₍₀₎, u₍₁₎, . . . u_{(H-1)} by H component polar matrix sizes N₀, N₁, . . . , N_{H-1} as below:

```
i = 0;
For h = 0 to H−1
  For k = 0 to Nₕ−1
    uₖ^{(h)} = uᵢ;
    i = i + 1;
  End for
End for
```

In the above example, the segmentation input bit sequence of length E is the pre-transform output bit sequence u=[u₀, u₁, u₂, . . . , u_{E-1}] of length E; for h=0, 1, . . . , H−1, the h-th segmentation output bit sequence u ^{(h)} is of length equal to the h-th component polar matrix size Nₕ. In some embodiments, the segmentation input bit sequence of length E consists of the H segmentation output bit sequences u₍₀₎, u₍₁₎, . . . u_{(H-1)}.

In some examples, a segmentation block can be connected to one or more component polar transform blocks.

Examples are given in FIGS. 4A to 4C.

### Embodiment 9

This section discloses examples involving polar transforms.

Embodiment 9 is based on all the above embodiments.

An encoding or decoding system may contains multiple component polar transforms.

The input of the component polar transforms can be based on the input sequence c.

In some examples, a component polar transform block can be connected with a segmentation block.

In one example, for h=0, 1, 2, . . . , H−1, the h-th segmentation output bit sequences u^{(h)} of length Nₕ is input to a component polar transform to determine an h-th component polar transform output bit sequence d^{(h)}=[d₀^{(h)}, d₁^{(h)}, . . . , d_{N}_{ₕ}₋₁^{(h)}] of length N, by the h-th component polar matrix G^{(N}^{ₕ}⁾ as d^{(h)}=u^{(h)}·G^{(N}^{ₕ}⁾, wherein, the component polar transform is a vector-matrix multiplication of the h-th segmentation output bit sequences u^{(h)} of length Nₕ and the component polar matrix G^{(N}^{ₕ}⁾ over GF(2) to obtain h-th component polar transform output bit sequence d^{(h)} =[d₀^{(h)}, d₁^{(h)}, . . . , d_{N}_{ₕ}₋₁^{(h)}], i.e., d^{(h)}=u^{(h)}·G^{(N}^{ₕ}⁾.

In some examples, a component polar transform block can be connected with a component interleaving block. In one example, the input of a component interleaving block is based on the output of a component polar transform block.

Some examples are shown in FIGS. 4A to 4C.

### Embodiment 10

This section discloses examples involving output bit sequence comprises component polar transform output bit sequences.

Embodiment 10 is based on the above embodiments.

In one example, the output bit sequence e=[e₀, e₁, . . . , e_{E-1}] comprises H component polar transform output bit sequences d⁽⁰⁾, d⁽¹⁾, . . . , d^{(H-1)}, wherein, for h=0, 1, . . . , H−1, the h-th component polar transform output bit sequence d^{(h)}=[d₀^{(h)}, d₁^{(h)}, . . . , d_{N}_{ₕ}₋₁^{(h)}] is of length equal to the h-th component polar matrix size Nₕ.

In another example, the output bit sequence e=[e₀, e₁, . . . , e_{E-1}] is a second concatenation of H component polar coding output bit sequences d⁽⁰⁾, d⁽¹⁾, . . . , d^{(H-1)} as follows: [e₀, e₁, e₂, . . . , e_{E-1}]=[d⁽⁰⁾, d⁽¹⁾, . . . , d^{(H-1)}]=[d₀⁽⁰⁾, d₁⁽⁰⁾, . . . d_{N}_{₀}₋₁⁽⁰⁾, d₀⁽¹⁾, d₁⁽¹⁾, . . . , d_{N}_{₁}₋₁^{(h)}, . . . , d₀^{(H-1)}, d₁^{(H-1)}, . . . , d_{N}_{_{H−1}}₋₁^{(H-1)}].

In yet another example, the output bit sequence e=[e₀, e₁, . . . , e_{E-1}] is a second concatenation of H component polar coding output bit sequences d⁽⁰⁾, d⁽¹⁾, . . . , d^{(H-1)} as follows:

```
i = 0;
For h = 0 to H−1
  For k = 0 to Nₕ−1
    eᵢ = dₖ^{(h)};
    i = i + 1;
  End for
End for
```

FIG. 4A gives an example for the output bit sequence e being a concatenation of H component polar coding output bit sequences d⁽⁰⁾, d⁽¹⁾, . . . , d^{(H-1)}.

### Embodiment 11

This section discloses example systems comprising component interleaving.

Embodiment 11 is based all of the above Embodiments.

A component interleaving operation can be achieved based on an interleaver pattern J.

In some examples, for h=0, 1, . . . , W−1, the h-th component polar transform output bit sequence d^{(h)}=[d₀^{(h)}, d₁^{(h)}, . . . , d_{N}_{ₕ}₋₁^{(h)}] is input to an h-th component interleaving to determine an h-th component interleaving output bit sequence d′^{(h)}=[d′₀^{(h)}, d′₁^{(h)}, . . . , d′_{N}_{ₕ}₋₁^{(h)}], wherein, the h-th component interleaving is determined by the h-th component interleaver pattern J^{(h)}=[J₀^{(h)}, J₁^{(h)}, . . . , J_{N}_{ₕ}₋₁^{(h)}] of length Nₕ, wherein Nₕ is the h-th component polar matrix size.

In some embodiments, the h-th component interleaver pattern J^{(h)} is determined using the method in Example 1 with a polar matrix size N=Nₕ, wherein Nₕ is the h-th component polar matrix size. In some embodiments, the h-th component interleaver pattern J^{(h)}is determined using the method in Example 2 with a polar matrix size N=Nₕ, wherein Nₕ is the h-th component polar matrix size.

In another example, a component interleaving determined by an component interleaver pattern J=[J₀, J₁, . . . , J_{N-2}, J_{N-1}] of length N comprises obtaining, by the first node, a component interleaving input bit sequence d=[d₀, d₁, . . . , d_{N-1}] of length N; and determining, by the first node, a component interleaving output bit sequence d′=[d′₀, d′₁, . . . , d′_{N-1}] of length N as d′ᵢ=d_{J}_{ᵢ}, i=0, 1, 2, . . . , N−2, N−1.

In other words, the i-th bit of the interleaving output bit sequence d′ is equal to the Jᵢ-th bit of the interleaving input bit sequence d=[d₀, d₁, . . . , d_{N-1}], wherein, the component interleaver pattern J can be any permutation of the integer sequence [0, 1, 2, . . . , N−2, N−1].

Several examples are discussed below to indicate the interleaving process mentioned above.

Example 1: A first specific example of a component interleaver pattern J=[J₀, J₁, . . . , J_{N-2}, J_{N-1}] is determined as by a polar matrix size N and a sub-block interleaver pattern π=[π₀, π₁, π₂, π₃, π₄, π₅, π₆, π₇, π₈, π₉, π₁₀, π₁₁, π₁₂, π₁₃, π₁₄, π₁₅, π₁₆, π₁₇, π₁₈, π₁₉, π₂₀, π₂₁, π₂₂, π₂₃, π₂₄, π₂₅, π₂₆, π₂₇, π₂₈, π₂₉, π₃₀, π₃₁]=[0, 1, 2, 4, 3, 5, 6, 7, 8, 16, 9, 17, 10, 18, 11, 19, 12, 20, 13, 21, 14, 22, 15, 23, 24, 25, 26, 28, 27, 29, 30, 31] as follows.

```
For i = 0 to N−1
  j = floor(32i/N);
  Jᵢ= πⱼ×(N/32) + mod(i, N/32);
End for
```

Example 2: A second specific example of an interleaver pattern J=[J₀, J₁, . . . , J_{N-2}, J_{N-1}] is that the relationship between the index i and the i-th element Ji in the interleaver pattern J satisfies the following quadratic form:

Jᵢ=mod(f₁·i+f₂·i², N)

where some examples of parameters f₁ and f₂ depending on a polar matrix size N are summarized in TABLE 1.

TABLE 1
Interleaver parameters for Example 2

| N | f₁ | f₂ |
|---|---|---|
| 64 | 7 | 16 |
| 128 | 15 | 32 |
| 256 | 15 | 32 |
| 512 | 31 | 64 |
| 1024 | 31 | 64 |
| 2048 | 31 | 64 |
| 4096 | 31 | 64 |

Example 3: A third example of a component interleaver pattern J=[J₀, J₁, . . . , J_{N-2}, J_{N-1}] with N=8 is J=[J₀, J₁, J₂, J₃, J₄, J₅, J₆, J₇]=[5, 4, 7, 1, 6, 0, 2, 3].

### Embodiment 12

This section discloses examples of output bit sequences include component interleaving output bit sequences.

Embodiment 12 is based on all the Embodiments disclosed above.

In some embodiments, the output bit sequence e=[e₀, e₁, . . . , e_{E-1}] comprises W component interleaving output bit sequences d′⁽⁰⁾, d′⁽¹⁾, . . . , d′^{(W-1)} and H−W component polar transform output bit sequences d^{(W)}, d^{(W+1)}, . . . , d^{(H-1)}, wherein, for h=0, 1, . . . , W−1, the h-th component interleaving output bit sequence d′^{(h)}=[d′₀^{(h)}, d′₁^{(h)}, . . . , d′_{N}_{ₕ}₋₁^{(h)}] is of length equal to the h-th component polar matrix size Nₕ and for h=W, W+1, . . . , H−1, the h-th component polar transform output bit sequence d^{(h)}=[d₀^{(h)}, d₁^{(h)}, . . . , d_{N}_{ₕ}₋₁^{(h)}] is of length equal to the h-th component polar matrix size Nₕ.

In some embodiments, the output bit sequence e=[e₀, e₁, . . . , e_{E-1}] is a second concatenation of W=H component interleaving output bit sequences d′⁽⁰⁾, d′⁽¹⁾, . . . , d′^{(H-1)} as follows:

[e₀, e₁, e₂, . . . , e_{E-1}]=[d′⁽⁰⁾, d′⁽¹⁾, . . . , d′^{(H-1)}]=[d′₀⁽⁰⁾, d′₁⁽⁰⁾, . . . d′_{N}_{₀}₋₁⁽⁰⁾, d′₀⁽¹⁾, d′₁⁽¹⁾, . . . , d′_{N}_{₁}₋₁^{(h)}, . . . , d′₀^{(H-1)}, d′₁^{(H-1)}, . . . , d′_{N}_{_{H−1}}₋₁^{(H-1)}].

In some embodiments, the output bit sequence e=[e₀, e₁, . . . , e_{E-1}] is a second concatenation of W=H component output bit sequences d′⁽⁰⁾, d′⁽¹⁾, . . . , d′^{(H-1) a}s follows:

```
i = 0;
For h = 0 to H−1
  For k = 0 to Nₕ−1
    eᵢ = d′ₖ^{(h)};
    i = i + 1;
  End for
End for
```

FIG. 4B discloses an example for the output bit sequence e being a concatenation of W=H component interleaving output bit sequences d′⁽⁰⁾, d′⁽¹⁾, . . . , d′^{(H-1)}.

In some examples, the output bit sequence e=[e₀, e₁, . . . , e_{E-1}] is a second concatenation of W component interleaving output bit sequences d′⁽⁰⁾, d′⁽¹⁾, . . . , d′^{(W-1)} and H−W component polar transform output bit sequences d^{(W)}, d^{(W+1)}, . . . , d^{(H-1)} as follows:

[e₀, e₁, e₂, . . . , e_{E-1}]=[d′⁽⁰⁾, d′⁽¹⁾, . . . , d′^{(W-1)}, d^{(W)}, d^{(W+1)}, . . . , d^{(H-1)}]=[d′₀⁽⁰⁾, . . . d′_{N}_{₀}₋₁⁽⁰⁾, . . . . , d′₀^{(W-1)}, . . . , d′_{N}_{_{W−1}}₋₁^{(W-1)}, d₀^{(W)}, . . . , d_{N}_{_{W}}₋₁^{(W)}, . . . , d₀^{(H-1)}, . . . , d_{N}_{_{H−1}}₋₁^{(H-1)}].

In some embodiments, the output bit sequence e=[e₀, e₁, . . . , e_{E-1}] is a second concatenation of W component interleaving output bit sequences d′⁽⁰⁾, d′⁽¹⁾, . . . , d′^{(W-1)} and H−W component polar transform output bit sequences d^{(W)}, d^{(W+1)}, . . . , d^{(H-1)} as follows:

```
i = 0;
For h = 0 to W−1
  For k = 0 to Nₕ−1
    eᵢ = d′ₖ^{(h)};
    i = i + 1;
  End for
End for
For h = W to H−1
  For k = 0 to Nₕ−1
    eᵢ = dₖ^{(h)};
    i = i + 1;
  End for
End for
```

FIG. 4C gives a specific example for the output bit sequence e being a concatenation of W component interleaving output bit sequences d′⁽⁰), d′⁽¹⁾, . . . , d′^{(W-1)} and H−W component polar transform output bit sequences d′^{(W)}, d′^{(W+1)}, . . . , d′^{(H-1)}, wherein the number of interleaver patterns is smaller than the number of component polar matrices, i.e., W<H.

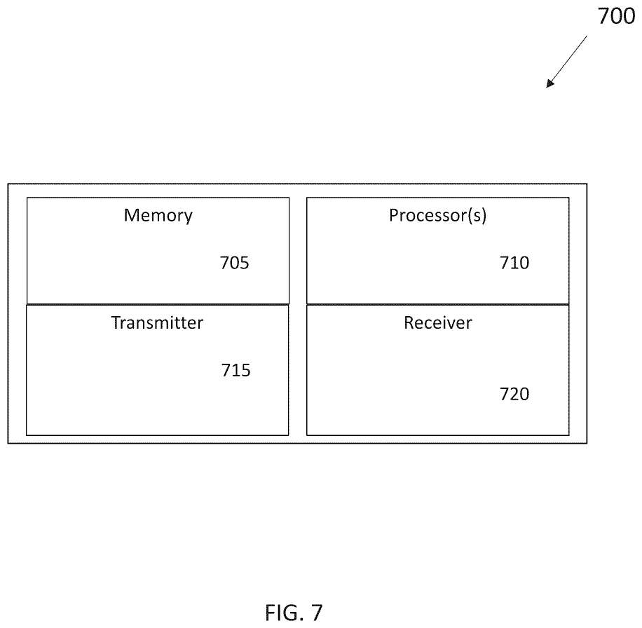

FIG. 7 shows an exemplary block diagram of a hardware platform 700 that may be a part of a network device (e.g., base station) or a communication device (e.g., a user equipment (UE)). The hardware platform 700 includes at least one processor 710 and a memory 705 having instructions stored thereupon. The instructions upon execution by the processor 710 configure the hardware platform 700 to perform the operations described in FIGS. 1 to 6 and in the various embodiments described in this patent document. The transmitter 715 transmits or sends information or data to another device. For example, a network device transmitter can send a message to user equipment. The receiver 720 receives information or data transmitted or sent by another device. For example, user equipment can receive a message from a network device.

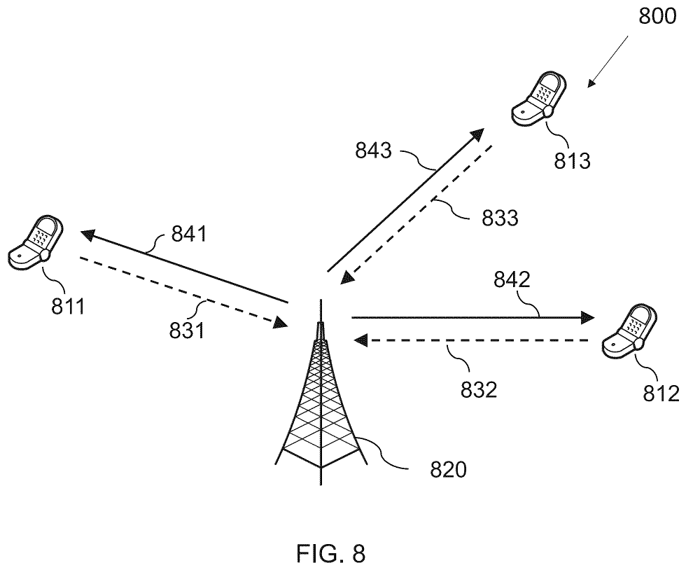

The implementations as discussed above will apply to a network communication. FIG. 8 shows an example of a communication system (e.g., a 5G or NR cellular network) that includes a base station 820 and one or more user equipment (UE) 811, 812 and 813. In some embodiments, the UEs access the BS (e.g., the network) using a communication link to the network (sometimes called uplink direction, as depicted by dashed arrows 831, 832, 833), which then enables subsequent communication (e.g., shown in the direction from the network to the UEs, sometimes called downlink direction, shown by arrows 841, 842, 843) from the BS to the UEs. In some embodiments, the BS send information to the UEs (sometimes called downlink direction, as depicted by arrows 841, 842, 843), which then enables subsequent communication (e.g., shown in the direction from the UEs to the BS, sometimes called uplink direction, shown by dashed arrows 831, 832, 833) from the UEs to the BS. The UE may be, for example, a smartphone, a tablet, a mobile computer, a machine to machine (M2M) device, an Internet of Things (IoT) device, and so on.

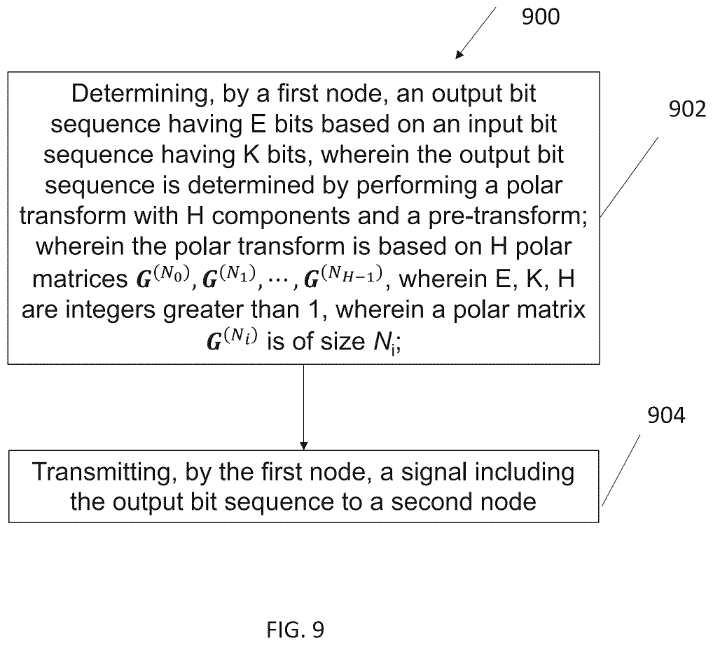

FIG. 9 shows an example flowchart representation of a method for digital communication in accordance with one or more embodiments of the present technology. Operation 902 includes determining, by a first node, an output bit sequence having E bits based on an input bit sequence having K bits, wherein the output bit sequence is determined by performing a polar transform with H components and a pre-transform; wherein the polar transform is based on H polar matrices G^{(N}^{₀}⁾, G^{(N}^{₁}⁾, . . . , G^{(N}^{_{H−0}}⁾, wherein E, K, H are integers greater than 1, wherein a polar matrix G^{(N}^{ᵢ}⁾ is of size Nᵢ. Operation 904 includes transmitting, by the first node, a signal including the output bit sequence to a second node.

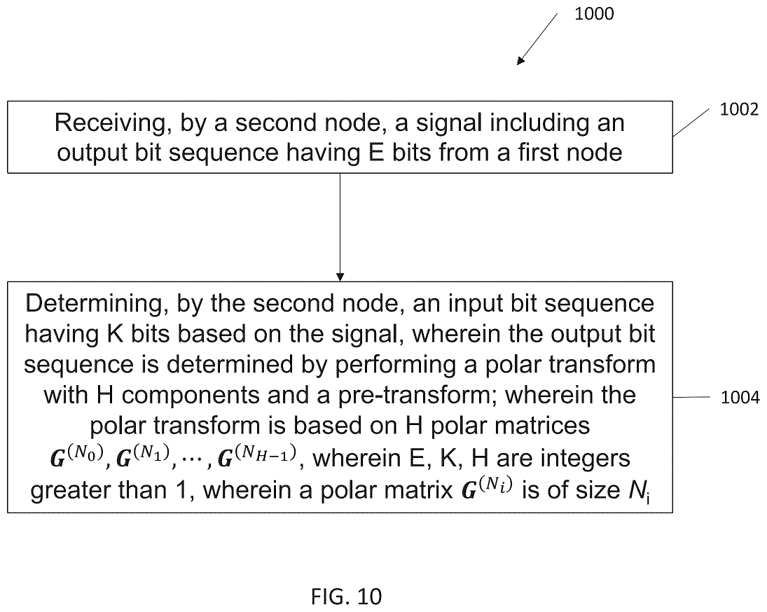

FIG. 10 shows another example flowchart representation of a method for digital communication in accordance with one or more embodiments of the present technology. Operation 1002 includes receiving, by a second node, a signal including an output bit sequence having E bits from a first node. Operation 1004 includes determining, by the second node, an input bit sequence having K bits based on the signal, wherein the output bit sequence is determined by performing a polar transform with H components and a pre-transform; wherein the polar transform is based on H polar matrices G^{(N}^{₀}⁾, G^{(N}^{₁}⁾, . . . , G^{(N}^{_{H−0}}⁾, wherein E, K, H are integers greater than 1, wherein a polar matrix G^{(N}^{ᵢ}⁾ is of size Nᵢ.

Various preferred embodiments and additional features of the above-described methods of FIGS. 9 and 10 are as follows. Further examples are described with reference to embodiments 1 to 12. In some embodiments, at least two of the H polar matrices have different sizes. In some embodiments, at least two of the H polar matrices are different. In some embodiments, at least two of the H polar matrices have sizes greater than 2. In some embodiments, N₀, N₁, . . . , N_{H-1} and E satisfy N₀+N₁+ . . . +N_{H-1}=E. In some embodiments, E is determined by the summation of N₀, N₁, . . . , N_{H-1}. In some embodiments, each of N₀, N₁, . . . , N_{H-1} is an integer being a power of 2. In some embodiments, the output bit sequence is determined by further performing a repetition operation, wherein the input of the repetition operation is based on the input bit sequence.

In some embodiments, the repetition operation comprising: obtaining, by the first node, a repetition input bit sequence; and determining, by the first node, H component repetition output bit sequences c⁽⁰⁾, c⁽¹⁾, . . . , c^{(H-1)} based on at least one of: 1) a length list (K₀, K₁, . . . , K_{H-1}), wherein Kᵢ indicating the length of c⁽ⁱ⁾ or 2) a repetition index list (R⁽⁰⁾, R⁽¹⁾, . . . , R^{(H-1)}). In some embodiments, at least one of the H component repetition output bit sequences c⁽⁰⁾, c⁽¹⁾, . . . , c^{(H-1)} has a length equal to the length of the input bit sequence. In some embodiments, none of the H component repetition output bit sequences c⁽⁰⁾, c⁽¹⁾, . . . , c^{(H-1)} has a length equal to the length of the input bit sequence. In some embodiments, at least one of the H component repetition output bit sequences c⁽⁰⁾, c⁽¹⁾, . . . , c^{(H-1)} is equal to the input bit sequence. In some embodiments, at least one element Kᵢ in the length list (K₀, K₁, . . . , K_{H-1}) is equal to K, wherein K is the length of the input bit sequence. In some embodiments, an element R⁽ⁱ⁾ in the repetition index list (R⁽⁰⁾, R⁽¹⁾, . . . , R^{(H-1)}) is an integer set. In some embodiments, at least one element R⁽ⁱ⁾ in the repetition index list (R⁽⁰⁾, R⁽¹⁾, . . . , R^{(H-1)}) is equal to a first-type integer set Z_{K}={0, 1, 2, . . . , K−1}, wherein the first-type integer set Z_{K}={0, 1, 2, . . . , K−1} comprises all non-negative integers smaller than K and K is the length of the input bit sequence. In some embodiments, for h=0, 1, . . . , H−2, R^{(h+1)} is a subset of R^{(h)}. In some embodiments, at least two of the H component repetition output bit sequences share at least one common element. In some embodiments, c^{(h)}=[c₀^{(h)}, c₁^{(h)}, . . . , c_{K}_{ₕ}₋₁^{(h)}], wherein Kₕ is a positive integer. In some embodiments, at least two of the H component repetition output bit sequences c⁽ⁱ⁾ and c^{(j)} are determined based on at least one element cₖ. In some embodiments, the at least one element cₖ is determined based on at least one bit in the input bit sequence. In some embodiments, at least two of the H component repetition output bit sequences c⁽ⁱ⁾ and c^{(j)} are determined based on at least one same bit in the input bit sequence. In some embodiments, at least two of the H component repetition output bit sequences c⁽ⁱ⁾ and c^{(j)} comprise common sub-sequences of the input bit sequence.

In some embodiments, at least two of the H component repetition output bit sequences c⁽ⁱ⁾ and c^{(j)} comprise matching sub-sequences generated based on the input bit sequence. In one example, an input bit sequence c=[c₀, c₁, c₂, c₃, c₄, c₅, c₆, c₇, c₈], c⁽ⁱ⁾=[c₀, c₁, c₇, c₃] and c^{(j)}=[c₃, c₂, c₇, c₅]. Here, c⁽ⁱ⁾ and c^{(j)} have matching subsequences [c₇, c₃] and [c₃, c₇] accordingly. Both matching sub-sequences are generated based on the input sequence c, i.e., the elements c₃ and c₇ are in the input sequence c. Also, the two sub-sequences [c₇, c₃] and [c₃, c₇] have a matching relationship, e.g., the third and fourth elements in c⁽ⁱ⁾ (c₇ and c₃) determine the third and first elements (c₇ and c₃) in c^{(j)} . The two matching subsequences do not need to be in the same order with each other. Also, the elements in a matching subsequence do not need to be in consecutive positions in c⁽ⁱ⁾ or c^{(j)}.

In some embodiments, the output bit sequence is determined by further performing a rate profile operation, wherein the input of the rate profile operation is based on the input bit sequence. In some embodiments, the rate profile operation is performed on the input bit sequence c=[c₀, c₁, . . . , c_{K-1}] using a first data bit index set Q={Q₀, Q₁, . . . , Q_{K-1}} to obtain a repetition rate profile output bit sequence v′=[v′₀, v′₁, . . . , v′_{N-1}].

In some embodiments, the output bit sequence is determined by further performing a repetition operation, wherein the repetition operation comprises: determining, by the first node, H component repetition output bit sequences c⁽⁰⁾, c⁽¹⁾, . . . , c^{(H-1)} based on the repetition rate profile output bit sequence v′=[v′₀, v′₁, . . . , v′_{N-1}] by at least one of: 1) a length list (K₀, K₁, . . . , K_{H-1}), wherein Kᵢ indicating the length of c⁽ⁱ⁾ or 2) the first data bit index set Q={Q₀, Q₁, . . . , Q_{K-1}}. In some embodiments, at least one of the H component repetition output bit sequences c⁽⁰⁾, c⁽¹⁾, . . . , c^{(H-1)} has a length equal to the length of the input bit sequence. In some embodiments, none of the H component repetition output bit sequences c⁽⁰⁾, c⁽¹⁾, . . . , c^{(H-1)} has a length equal to the length of the input bit sequence. In some embodiments, at least one of the H component repetition output bit sequences c⁽⁰⁾, c⁽¹⁾, . . . , c^{(H-1)} is equal to the input bit sequence. In some embodiments, at least one element Kᵢ in the length list (K₀, K₁, . . . , K_{H-1}) is equal to K, wherein K is the length of the input bit sequence. In some embodiments, the first data bit index set Q={Q₀, Q₁, . . . , Q_{K-1}} is sorted according to index values or reliability of polarized sub-channels. In some embodiments, at least two of the H component repetition output bit sequences share at least one common element. In some embodiments, c^{(h)}=[c₀^{(h)}, c₁^{(h)}, . . . , c_{K}_{ₕ}₋₁^{(h)}], wherein Kₕ is a positive integer. In some embodiments, at least two of the H component repetition output bit sequences c⁽ⁱ⁾ and c^{(j)} are determined based on at least one element v′ₖ. In some embodiments, the element is determined based on at least one bit in v′ₖ is determined based on at least one bit in the repetition rate profile output bit sequence v′=[v′₀, v′₁, . . . , v′_{N-1}], where N is an integer larger than 1. In some embodiments, at least two of the H component repetition output bit sequences c⁽ⁱ⁾ and c^{(j)} are determined based on at least one same bit in the repetition rate profile output bit sequence v′=[v′₀, v′₁, . . . , v′_{N-1}], where N is an integer larger than 1. In some embodiments, at least two of the H component repetition output bit sequences c⁽ⁱ⁾ and c^{(j)} comprise common sub-sequences in the repetition rate profile output bit sequence v′=[v′₀, v′₁, . . . , v′_{N-1}], where N is an integer larger than 1.

In some embodiments, at least two of the H component repetition output bit sequences c⁽ⁱ⁾ and c^{(j)} comprise matching sub-sequences in the repetition rate profile output bit sequence v′=[v′₀, v′₁, . . . , v′_{N-1}], where N is an integer larger than 1. In one example, a repetition rate profile output bit sequence v′=[v′₀, v′₁, v′₂, v′₃, v′₄, v′₅, v′₆, Y′₇], c⁽ⁱ⁾=[v′₀, v′₁, v′₂] and c^{(j)}=[v′₂, v′₁, v′₄]. Here, c⁽ⁱ⁾ and c^{(j)} have matching subsequences [v′₁, v′₂] and [v′₂, v′₁] accordingly. Both matching subsequences are generated based on the repetition rate profile output bit sequence v′, i.e., the elements v′₁ and v′₂ are in the repetition rate profile output bit sequence v′. Also, the two subsequences [v′₁, v′₂] and [v′₂, v′₁] have a matching relationship, e.g., the second and third elements in c⁽ⁱ⁾ (v′₁ and v′₂) map to the second and first elements (v′₁ and v′₂) in c^{(j)}. The two matching subsequences do not need to be in the same order with each other. Also, the elements in a matching subsequence do not need to be in consecutive positions in c⁽ⁱ⁾ or c^{(j)}.

In some embodiments, the rate profile operation is performed with H components. In some embodiments, the h-th component of the rate profile operation is performed based on a component data bit set Q^{(h)}={Q₀^{(h)}, Q₁^{(h)}, Q₂^{(h)}, . . . , Q_{K}_{ₕ}^{(h)}}, wherein Kₕ is the input length of the h-th component of the rate profile operation.

In some embodiments, the above introduced methods further comprising performing a first concatenation operation, wherein the input of the first concatenation operation is based on the input sequence. In some embodiments, the first concatenation operation generates an intermediate output sequence having E bits. In some embodiments, the first concatenation operation is performed on a first H components bit sequences generated based on the input sequence.

In some embodiments, the above introduced methods further comprising performing a second concatenation operation, wherein the input of the second concatenation operation is based on the input sequence. In some embodiments, a second concatenation operation is performed on a second H components bit sequences generated based on the input sequence.

In some embodiments, the pre-transform generates an intermediate bit sequence having E bits. In some embodiments, a bit of the intermediate bit sequence is determined by a convolution bit sequence or a convolution polynomial. In some embodiments, the convolution bit sequence comprises a generator bit sequence g=[g₀, g₁, . . . , gₘ], or a recursive feedback bit sequence q=[q₀, q₁, . . . , qₘ], wherein m is a positive integer. In some embodiments, the convolution polynomial comprises a generator polynomial g(D)=g₀+g₁·D+ . . . +gₘ₋₁·D^{m-1}+gₘ·D^{m}, or a recursive feedback polynomial q(D)=q₀+q₁·D+ . . . +qₘ₋₁·D^{m-1}+qₘ·D^{m}, wherein m is a positive integer. In some embodiments, the output bit sequence is determined by performing a segmentation operation, wherein the input of the segmentation operation is based on the input bit sequence.

In some embodiments, the output bit sequence is determined further by performing an interleaving operation, wherein the input of the interleaving operation is based on the input bit sequence. In some embodiments, the interleaving operation is performed with W components, wherein W is an integer less than or equal to H. In some embodiments, the interleaving operation of any of the W components is determined by an interleaving pattern J^{(h)}=[J₀^{(h)}, J₁^{(h)}, . . . , J_{N}_{ₕ}₋₁^{(h)}] of length Nₕ, wherein Nₕ is an integer larger than 1.

It will be appreciated that the present document discloses methods and apparatus related to rate matching schemes applying to polar coding, PAC coding, or other pre-transformed polar coding. In 5G mobile communications standard of 3GPP, low-density parity-check (LDPC) codes are used for data transmission. However, LDPC has certain drawbacks compared to polar codes in short payload size (also called transport block size (TBS)). Alternatively, PAC codes can achieve finite-length bounds in moderate decoding complexity. PAC codes have code lengths with power of 2 (N=2ⁿ with positive integer n) as polar codes. However, to efficiently transmitting a payload (or transport block (TB)) in different wireless channel environments, it does not always have a code length of N=2ⁿ in time and frequency resources allocated by a base station (BS). Therefore, rate matching schemes are needed for applying PAC codes in wireless communications.

The disclosed and other embodiments, modules and the functional operations described in this document can be implemented in digital electronic circuitry, or in computer software, firmware, or hardware, including the structures disclosed in this document and their structural equivalents, or in combinations of one or more of them. The disclosed and other embodiments can be implemented as one or more computer program products, i.e., one or more modules of computer program instructions encoded on a computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. A propagated signal is an artificially generated signal, e.g., a machine-generated electrical, optical, or electromagnetic signal, that is generated to encode information for transmission to suitable receiver apparatus.

A computer program (also known as a program, software, software application, script, or code) can be written in any form of programming language, including compiled or interpreted languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this document can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

While this document contains many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or a variation of a subcombination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. A method for digital communication, comprising:
determining, by a first node, an output bit sequence having E bits based on an input bit sequence having K bits, wherein the output bit sequence is determined by performing a polar transform with H components and a pre-transform, wherein the polar transform is based on H polar matrices G^{(N}^{₀}⁾, G^{(N}^{₁}⁾, . . . , G^{(N}^{_{H−0}}⁾, wherein E, K, H are integers greater than 1, wherein a polar matrix G^{(N}^{ᵢ}⁾ is of size Nᵢ, and wherein at least two of the H polar matrices have different sizes; and
transmitting, by the first node, a signal including the output bit sequence to a second node.

2. The method of claim 1, wherein at least two of the H polar matrices have sizes greater than 2.

3. The method of claim 1, wherein each of N₀, N₁, . . . , N_{H-1} is an integer being a power of 2.

4. The method of claim 1, wherein the output bit sequence is determined by further performing a repetition operation, wherein an input of the repetition operation is based on the input bit sequence.

5. The method of claim 4, wherein the repetition operation comprises:
obtaining, by the first node, a repetition input bit sequence; and
determining, by the first node, H component repetition output bit sequences c⁽⁰⁾, c⁽¹⁾, . . . , c^{(H-1)} based on at least one of: 1) a length list (K₀, K₁, . . . , K_{H-1}), wherein Kᵢ indicating the length of c⁽ⁱ⁾ or 2) a repetition index list (R⁽⁰⁾, R⁽¹⁾, . . . , R^{(H-1)}) , wherein c⁽ⁱ⁾=[c₀⁽ⁱ⁾, c₁⁽ⁱ⁾, . . . , c_{K}_{ᵢ}₋₁⁽ⁱ⁾] and Kᵢ is a positive integer.

6. The method of claim 5, wherein at least two of the H component repetition output bit sequences share at least one common element.

7. The method of claim 5, wherein at least one of the H component repetition output bit sequences c⁽⁰⁾, c⁽¹⁾, . . . , c^{(H-1)} has a length equal to the length of the input bit sequence.

8. The method of claim 5, wherein at least two of the H component repetition output bit sequences c⁽ⁱ⁾ and c^{(j)} are determined based on at least one same bit in the input bit sequence.

9. The method of claim 5, wherein at least two of the H component repetition output bit sequences c⁽ⁱ⁾ and c^{(j)} comprise matching sub-sequences generated based on the input bit sequence.

10. The method of claim 5, wherein at least one element R⁽ⁱ⁾ in the repetition index list (R⁽⁰⁾, R⁽¹⁾, . . . , R^{(H-1)}) is equal to a first-type integer set Z_{K}={0, 1, 2, . . . , K−1}, wherein the first-type integer set Z_{K}={0, 1, 2, . . . , K−1} comprises all non-negative integers smaller than K.

11. A method for digital communication, comprising:
receiving, by a second node, a signal including an output bit sequence having E bits from a first node; and
determining, by the second node, an input bit sequence having K bits based on the signal, wherein the output bit sequence is determined by performing a polar transform with H components and a pre-transform, wherein the polar transform is based on H polar matrices G^{(N}^{₀}⁾, G^{(N}^{₁}⁾, . . . , G^{(N}^{_{H−0}}⁾, wherein E, K, H are integers greater than 1, and wherein a polar matrix G^{(N}^{ᵢ}⁾ is of size Ni.

12. The method of claim 11, wherein the output bit sequence is determined by further performing a rate profile operation, wherein the input of the rate profile operation is based on the input bit sequence.

13. The method of claim 12, wherein the rate profile operation is performed on the input bit sequence c=[c₀, c₁, . . . , c_{K-1}] using a first data bit index set Q={Q₀, Q₁, . . . , Q_{K-1}} to obtain a repetition rate profile output bit sequence v′=[v′₀, v′₁, . . . , v′_{N-1}].

14. The method of claim 13, wherein the output bit sequence is determined by further performing a repetition operation, wherein the repetition operation comprises: determining, by the first node, H component repetition output bit sequences c⁽⁰⁾, c⁽¹⁾, . . . , c^{(H-1)} based on the repetition rate profile output bit sequence v′=[v′₀, v′₁, . . . , v′_{N-1}] by at least one of: 1) a length list (K₀, K₁, . . . , K_{H-1}, wherein Kᵢ indicating the length of c⁽ⁱ⁾ or 2) the first data bit index set Q={Q₀, Q₁, . . . , Q_{K-1}}, wherein c⁽ⁱ⁾=[c₀⁽ⁱ⁾, c₁⁽ⁱ⁾, . . . , c_{K}_{ᵢ}₋₁⁽ⁱ⁾].

15. The method of claim 12, wherein the rate profile operation is performed with H components.

16. An apparatus for communication network, comprising at least one processor configured to cause the apparatus to:
determine an output bit sequence having E bits based on an input bit sequence having K bits, wherein the output bit sequence is determined by performing a polar transform with H components and a pre-transform, wherein the polar transform is based on H polar matrices G^{(N}^{₀}⁾, G^{(N}^{₁}⁾, . . . , G^{(N}^{_{H−0}}⁾, wherein E, K, H are integers greater than 1, wherein a polar matrix G^{(N}^{ᵢ}⁾ is of size Nᵢ, and wherein at least two of the H polar matrices have different sizes; and
transmit a signal including the output bit sequence to a second node.

17. The apparatus of claim 16, the processor is further configured to perform a first concatenation operation, wherein the input of the first concatenation operation is based on the input sequence.

18. The apparatus of claim 17, wherein the first concatenation operation generates an intermediate output sequence having E bits.

19. The apparatus of claim 17, wherein the first concatenation operation is performed on a first H component bit sequences generated based on the input sequence.

20. The apparatus of claim 16, wherein the pre-transform generates an intermediate bit sequence having E bits, wherein a bit of the intermediate bit sequence is determined by a convolution bit sequence or a convolution polynomial, wherein the convolution bit sequence comprises a generator bit sequence g=[g₀, g₁, . . . , gₘ] or a recursive feedback bit sequence q=[q₀, q₁, . . . , qₘ], wherein m is a positive integer, wherein the convolution polynomial comprises a generator polynomial g(D)=g₀+g₁·D+ . . . +gₘ₋₁·D^{m-1} +gₘ·D^{m} or a recursive feedback polynomial q(D)=q₀+q₁·D+ . . . +qₘ₋₁·D^{m-1} +qₘ·D^{m} , and wherein m is a positive integer.
